(19) United States
(12) Patent Application Publication
(10) Pub. No.: US 2004/0004863 A1
(43) Pub. Date: Jan. 8, 2004

(54) Nonvolatile electrically alterable memory device and array made thereby

(76) Inventor: Chih-Hsin Wang, San Jose, CA (US)

Correspondence Address: Chih-Hsin Wang, 6585 Gillis Dr., San Jose, CA, 95120, US

(21) Appl. No.: 10/608,800

(22) Filed: Jun. 28, 2003

Related U.S. Application Data
(60) Provisional application No. 60/393,848, filed on Jul. 5, 2002.

(51) Int. Cl. G11C 7/00

(52) U.S. Cl. 365/199

(57) ABSTRACT

A method of forming floating gate memory cells, and an array formed thereby, wherein each memory cell includes an electrical conductive floating gate having a folded structure over and adjacent to a semiconductor block on a semiconductor substrate. An electrical conductive control gate is formed having a portion disposed over and insulated from the floating gate. Spaced apart source and drain regions are formed self-aligned to source and drain lines with a channel region formed therebetween and along a top and sidewalls of the silicon block. An electrical conductive tunneling gate can be optionally provided over and insulated from the control gate by an insulating layer to form a tri-layer structure permitting both electron and hole charges tunneling through at similar tunneling rate.

This application claims the benefit of U.S. Provisional Application No. 60/393,848, filed Jul. 5, 2002, and entitled Folded Floating-Gate Nonvolatile Memory Cell and Array.

### TECHNICAL FIELD

The present invention deals with nonvolatile memory, and relates more specifically to Electrically Programmable Read Only Memories (EPROM) and Electrically Erasable and Programmable Read Only Memories (EEPROM). More particularly, the present invention relates to memory cell architecture, memory cell operation method, and methods forming cells and arrays of nonvolatile memory cell with floating gate.

### BACKGROUND OF THE INVENTION

Non-volatile semiconductor memory cells using a floating gate to store charges thereon and memory arrays of such non-volatile memory cells formed in a semiconductor substrate are well known in the art. Typically, the memory cell is electrically programmable and erasable by transporting charges in and out of a floating gate that is electrically insulated from but capacitively coupled to the surrounding electrodes. The amounts of charges retained in the floating gate define the states of a memory cell. Typically, the states thus defined can be either two levels or more than two levels (for multi-level states storage). The memory cell of such floating gate memory cells have been of the split gate type, or stacked gate type, or a combination thereof.

In current state-of-the-art nonvolatile memories, high voltage (typically ranging from 9 to 20V) is largely seen in cell operations (e.g. erase and program) in order to achieve desired memory states. Infrastructure for on-chip high voltage generation is thus essential to support the memory cell operations and has become an essential block in nonvolatile memories and products. The infrastructure involves separate sets of transistors used for handling high voltages and typically required adding at least 5 extra masks to a conventional CMOS technology. Therefore, it complicates process technology for nonvolatile memories.

Another issue on the high voltage infrastructure is its scalability along new generation technology. The high voltage is found un-scalable or difficult to be scaled due to the physics employed in memory cell operation. In a clear contrast, the operating voltage for logic circuits has been continuously scaled down in the past decades along with the scaling on minimum geometry of CMOS technology. Therefore, an increasingly larger gap between voltages operating the logic circuits and the memory cells is seen. The issue is more pronounced and aggravated as CMOS technology scaled beyond 0.25 um generation. As a result, a larger overhead, in terms of the area occupied by high voltage circuitry, is often seen in newer generation, memory products (in both stand-alone and embedded nonvolatile memory products). The scaling limit on high voltage further imposes constraints on the scaling of the minimum feature size for high-voltage transistors. Often, same sets of design rule for high-voltage transistors are used from one generation products to the next. Furthermore the high voltage operation introduces more issues in product functionality and reliability area.

U.S. Pat. No. 5,780,341 seek to overcome the problems by introducing a step channel/drain architecture into split gate type or stacked gate type cells, where electron charges are transported into floating gate through channel hot electron (CHE) or through source-side injection (SST) mechanisms. The charges are transported out of floating gate through Fowler-Nordheim tunneling mechanism. However, the mechanisms thus involved require high voltages to support the operation. It was shown the step channel/drain cell structure can help achieving higher efficiency for charge injection. Given the efforts thus devoted, nevertheless, it was shown the voltage as high as 10V still be essential for cell operations. It is believed that the high voltage demands stringent control on the quality of the insulator surrounding the floating gate. The structures thus are vulnerable to manufacturing and reliability issues.

U.S. Pat. No. 6,372,617 seeks to minimize the high voltage by forming floating gate in concave shape through forming polycrystalline silicon spacers atop of floating gate edges. The floating gate architecture thus formed can maximize the capacitive coupling between control gate and floating gate electrodes. Similar effort has also been devoted on the same subject by maximizing floating gate area through forming hemispherical grained polycrystalline silicon on floating gate of concave shape, where high voltage in cell operation is shown reducible to around 16V. Kitamura T. et al., “A Low Voltage Operating Flash Cell with High Coupling Ratio Using Horned Floating Gate with HSG”, Symposiulll on VSLI Technology Dig. Technical Papers, pp. 104-105 (1998). However, the polycrystalline silicon spacer formation for concave floating gate adds complexity to the process. In addition, the large topography of the concave floating gate adds difficulty on subsequent process steps (e.g. word-line formation). Both make manufacturing be difficult. Furthermore, the concave floating gate architecture introduces larger step height around floating gate edge, which increase floating gate-to-floating gate interference and is in general against cell-to-cell spacing scaling.

High voltage requirement for nonvolatile memory cells imposes constraints on cell scaling in prior arts aforementioned and hereinafter. For example, the high voltage handling capability of memory cells requires gate-length of a memory cell be long enough to avoid drain-to-source punch-through phenomenon. As a result, it imposes scaling barriers on new generation technology, in terms of the minimum feature size on transistor length of a memory cell. Similar to the issues encountered in high voltage transistors, the issue in cell scaling is more pronounced and aggravated as technology scaled beyond 0.25 μm generation. In terms of the cell physical size, the issue imposes a scaling constraint on the overall cell height (cell dimension typically defined in the bit-line direction).

Another main issue on the memories scaling is the minimum thickness of the oxide encapsulating the floating gate. A theoretical value of 5-6 nm has been reported as the limit for an intrinsic oxide layer, in order to avoid charge leakage due to the Fowler-Nordheim tunneling. K. Naruke et al, “Stress Induced Leakage Current Limiting to Scale Down EEPROM Tunnel Oxide Thickness”, IEDM Technical Digest, pp. 424-427, 1988. However, extra leakage current often is induced after oxide dielectrics undergo a high voltage stress. As a result of this, to maintain the same level of low leakage and hence to retain stored charges within the floating gate per typical product specifications, it has been consistently reported that a minimum thickness of about 8-9 nm be used in production over several technology generations. S. Lai, “Flash Memories: Where We Were and Where We Are Going”, IEDM Technical Digest, pp.971-973, 1998. This requirement on minimum oxide thickness limits the scalability of the cell channel width, when a minimum read current need be supplied from cells with a limited minimum gate-length. In terms of the cell physical size, the issue imposes a scaling constraint on the overall cell width (cell dimension typically detined in the word-line direction).

The issues outlined above on cell size scaling are commonly, seen in nonvolatile memory cells, e.g. cells with stacked gate EEPROM architecture, such as U.S. Pat. No. 4,957,877. The stacked gate cell architecture stack the control gate atop and insulated from the floating gate. The architecture and manufacturing method benefit the mature manufacturing technology on conventional EPROM due to the similar cell architectures and has become the main-stream technology in state-of-the-arts nonvolatile memory products. As the scaling issues aggravated, several new proposals have been disclosed to overcome the obstacles for achieving a more compact cell size. U.S. Pat. No. 5,146,426 disclosed floating-gate and control-gate of memory cell formed in a “contact hole”-like trench, whereas, U.S. Pat. No. 5,432,739 disclosed floating-gate and the control-gate of memory cell formed along sidewall of a pillar-like silicon region. These types of cells can achieve significantly smaller cell size than those in stacked gate EEPROM of an equivalent generation technology. However, these cells have drawbacks yet to be overcome. For example, U.S. Pat. No. 5,146,426 use cells with buried source biased at high voltage for erase operation. A thinning on gate dielectric around the trench corner is proposed to form a localized high field enhancing charge transport therein during an erase operation. Given the efforts, the operating voltage is still quite high and a stringent control on the oxide integrity is deemed essential. D. Kuo et al., “TEFET—A High Density, Low Erase Voltage, Trench Flash LEEPROM”, Symposium on VLSI Technology Dig. Technical Papers, pp. 51-52 (1994); H. Pein et al, “Performance of the 3-D Sidewall Flash EPROM Cell”, IEDM Technical Digest, pp. 11-14 (1993). In addition, a graded source junction is essential for this type of cell in order to sustain the high voltage. The high voltage in together with its operation through a buried source substantially adds limitations on achievable minimum spacing between the buried source regions and, therefore, restraints its future scaling. The constraints further complicate the memory array segmentation and block integration, which adversely enlarge the overall area of memory array, and therefore counteract its advantage on a smaller cell size. Furthermore, in U.S. Pat. No. 5,146,426, the trench bottom of each of the cells must be formed in the buried source within a tightly controlled depth in order for all the cells successfully operated during an erase operation. This stringent requirement is believed to introduce significant manufacturing difficulties. U.S. Pat. No. 5,432,739 use pillar-like cell for compact cell size. This type of cell relies on large topography for floating gate and control gate formation, where polycrystalline silicon spacers are largely employed. Other than the drawback on needs for high voltage, it is generally believed that the large topography of the pillars, and the stringent requirements on pillars spacing in word-line and bit line directions; add process complexity for forming polycrystalline silicon spacers, and hence make manufacturing difficult. In summary, the cell architectures disclosed in U.S. Pat. Nos. 5,146,426 and 5,432,739 have the advantage on achieving a more compact cell size. However, these arts all proposed cell architectures fundamentally different from the conventional EPROM-based cell architecture, and hence have little or no leverage on utilizing the mature manufacturing and product experience of conventional EPROM-based cells. As a result, cells in these arts are believed difficult to be manufactured.

U.S. Pat. No. 5,115,289 taught a field-effect transistor (“FET” hereinafter) utilizing physics similar to the “Three-Dimensional DIBL”.as described by Chih Hsin Wang et al, “Three-Dimensional DIBL for Shallow-Trench Isolated MOSFET's”,IEEE Trans. on Electron Devices, pp. 139-144, 1999. The FET in U.S. Pat. No. 5,115,289 itself cannot preserve information on logic state, and was shown only applicable to volatile semiconductor memory (e.g. Static Random-Access-Memory SRAM and Dynamic Random-Access-Memory DRAM) through a combination with other elements (e.g. capacitors, FETs) well-known in the art. Due to the nature of volatile memory, the memories lose the information stored therein upon turning off the power supply. The FET in U.S. Pat. No. 5,115,289 cannot be used for non-volatile memory. Moreover, the patent does not suggest the application of this physics to non-volatile memory cells (e.g. EEPROM), nor teaching the usage and the advantage of this physics to nonvolatile memory cell operations (e.g. program and erase, as disclosed in the present invention).

U.S. Pat. No. 6,479,863 taught a tunneling injector memory cell based on conventional stacked-gate cell architecture (e.g. U.S. Pat. No. 4,957,877) and the physics on tunnel-emission devices (see Mead, “The Tunnel-Emission Amplifier”, Proceedings of IRE, pp.359-361, 1960). The cell in U.S. Pat. No. 6,479,863 is believed unable to inject both types of carriers (i.e. electrons and holes) using a single injector electrode. For example, for an injector optimized for injecting electrons (for program operation), the cell will suffer a massive electron carriers back-flow while injecting hole charges using the same injector onto floatting gate for an erase operation. Similarly, for an injector optimized for injecting holes (for erase operation), the cell will suffer a massive hole carriers back-flow while injecting electron charges onto floating gate for a program operation. The massive back-flow of either type of charge can cause a severe loading on the bias circuits, and disable the injection capability of the charges and fail the intended cell operation. Further, the cell faces similar issues on cell scaling along the Width direction, as usually observed in memory cells employing stacked-gate architecture.

### BRIEF DESCRIPTION OF THE DRAWINGS

FIG. 1A is a cross sectional view of a non-volatile electrically alterable memory cell in accordance with the first embodiment of the present invention.

FIG. 1B is a cross sectional view of a non-volatile electrically alterable memory cell in accordance with the second embodiment of the present invention.

FIG. 1C is a cross sectional view of a non-volatile electrically alterable memory cell in accordance with the third embodiment of the present invention.

FIG. 1D is a cross sectional view of a non-volatile electrically alterable memory cell in accordance with the fourth embodiment of the present invention.

FIG. 2A is a top view of a semiconductor substrate used in the first step of the method of manufacturing memory cell in present invention.

FIG. 2B is a cross sectional view of the structure taken along the line CC′ in FIG. 2A showing the initial processing steps to form the non-volatile memory cells and array in accordance with the first embodiment of the present invention.

FIGS. 3-11 are top views of the structures showing in sequence the next step(s) in the formation of a non-volatile memory array and cells in accordance with the first embodiment of the present invention.

FIGS. 3A-11A are cross sectional views taken along the line A-A′ in FIGS. 3-11 illustrating in sequence the next steps in processing to form the non-volatile memory cells and array in accordance with the first embodiment of the present invention.

FIGS. 3C-11C are cross sectional views taken along the line C-C′ in FIGS. 3-11 illustrating in sequence the next steps in processing to form the non-volatile memory cells and array in accordance with the first embodiment of the present invention.

FIGS. 3D-11D are cross sectional views taken along the line D-D′ in FIGS. 3-11 illustrating in sequence the next steps in processing to form the non-volatile memory cells and array in accordance with the first embodiment of the present invention.

FIGS. 8B-11B fire cross sectional views taken along the line B-B′ in FIGS. 8-11 illustrating in sequence the next steps in processing to form the non-volatile memory cells and array in accordance with the first embodiment of the present invention.

FIG. 12 is the schematics showing the array architecture for memory cells in accordance with the first embodiment of the present invention.

FIG. 13 is a cross sectional view of the structure taken along the line CC′ in FIG. 2A showing the initial processing steps to form the non-volatile memory cells and array in accordance with the second embodiment of the present invention.

FIGS. 14-21 are top views of the structures showing in sequence the next step(s) in the formation of a non-volatile memory cells and array in accordance with the second embodiment of the present invention.

FIGS. 14A-21A are cross sectional views taken along the line A-A′ in FIGS. 14-21 illustrating in sequence the next steps in processing to form the non-volatile memory cells and array in accordance with the second embodiment of the present invention.

FIGS. 14C-21C are cross sectional views taken along the line C-C′ in FIGS. 14-21 illustrating in sequence the next steps in processing to form the non-volatile memory cells and array in accordance with the second embodiment of the present invention.

FIGS. 14D-21D are cross sectional views taken along the line D-D′ in FIGS. 14-21 illustrating in sequence the next steps in processing to form the non-volatile memory cells and array in accordance with the second embodiment of the present invention.

FIGS. 18B-21B are cross sectional views taken along the line B-B′ in FIGS. 18-21 illustrating in sequence the next steps in processing to form the non-volatile memory cells and array in accordance with the second embodiment of the present invention.

FIGS. 22-28 are top views of the structures showing in sequence the next step(s) in the formation of a non-volatile memory cells and array in accordance with the third embodiment of the present invention.

FIGS. 22A-28A are cross sectional views taken along the line A-A′ in FIGS. 22-28 illustrating in sequence the next steps in processing to form the non-volatile memory cells and array in accordance with the third embodiment of the present invention.

FIGS. 22C-28C are cross sectional views taken along the line C-C′ in FIGS. 22-28 illustrating in sequence the next steps in processing to form the non-volatile memory cells and array in accordance with the third embodiment of the present invention.

FIGS. 22D-28D are cross sectional views taken along the line D-D′ in FIGS. 22-28 illustrating in sequence the next steps in processing to form the non-volatile memory cells and array in accordance with the third embodiment of the present invention.

FIGS. 24B-28B are cross sectional views taken along the line B-B′ in FIGS. 24-28 illustrating in sequence the next steps in processing to form the non-volatile memory cells and array in accordance with the third embodiment of the present invention.

FIGS. 29-30 are top views of the structures showing in sequence the next step(s) in the formation of a non-volatile memory cells and array in accordance with the fourth embodiment of the present invention.

FIGS. 29A-30A are cross sectional views taken along the line A-A′ in FIGS. 29-30 illustrating in sequence the next steps in processing to form the non-volatile memory cells and array in accordance with the fourth embodiment of the present invention.

FIGS. 29B-30B are cross sectional views taken along the line B-B′ in FIGS. 29-30 illustrating in sequence the next steps in processing to form the non-volatile memory cells and array in accordance with the fourth embodiment of the present invention.

FIGS. 29C-30C are cross sectional views taken along the line C-C′ in FIGS. 29-30 illustrating in sequence the next steps in processing to form the non-volatile memory cells and array in accordance with the fourth embodiment of the present invention.

FIGS. 29D-30D are cross sectional views taken along the line D-D′ in FIGS. 29-30 illustrating in sequence the next steps in processing to form the non-volatile memory cells and array in accordance with the fourth embodiment of the present invention.

FIG. 31 is the schematics showing the array architecture for memory cells in accordance with the fourth embodiment of the present invention.

### DETAILED DESCRIPTION OF VARIOUS EMBODIMENTS

In accordance with a preferred embodiment, the present invention makes use of the “Three-Dimensional DIBL” phenomenon to solve the aforementioned problems and to improve cell performance in non-volatile memory devices for extended applications. Specifically, the present invention discloses cell architecture utilizing the “Three-Dimensional DIBL” phenomenon to suppress the drain-to-source punch-through leakage, addressing the scaling issue on cell length direction described hereinbefore. In addition, the present invention makes use of the same phenomenon to enhance the hot-carriers injection efficiency (number of electrons injected compared to total number of electrons) for nonvolatile memory operations. Furthermore, the floating-gate is folded to control the recessed channel regions. This increases the effective channel width of a unit cell, addressing the scaling issue on cell width direction described hereinbefore.

Various features of the present invention will become apparent by a review of the description, specification, claims and appended figures.

Memory Cell

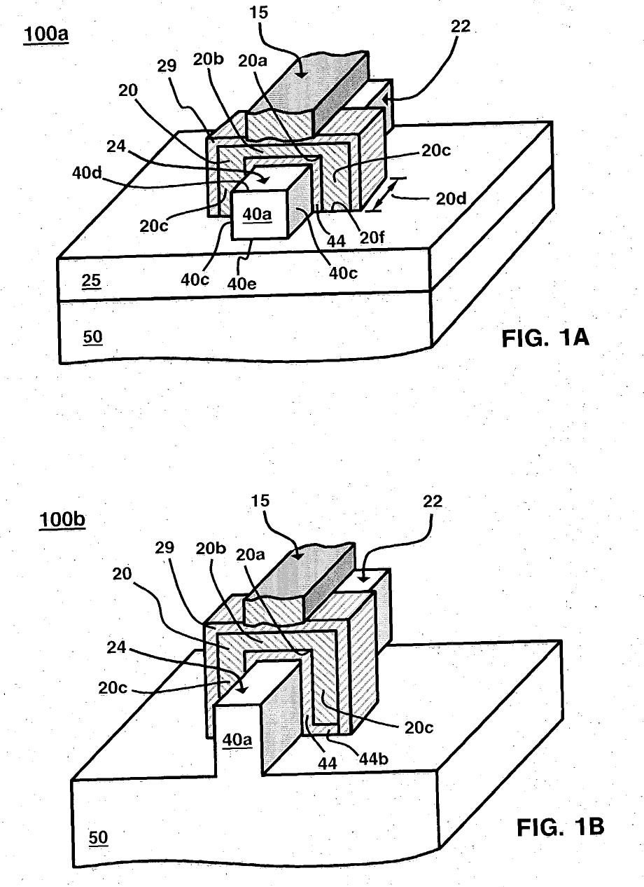

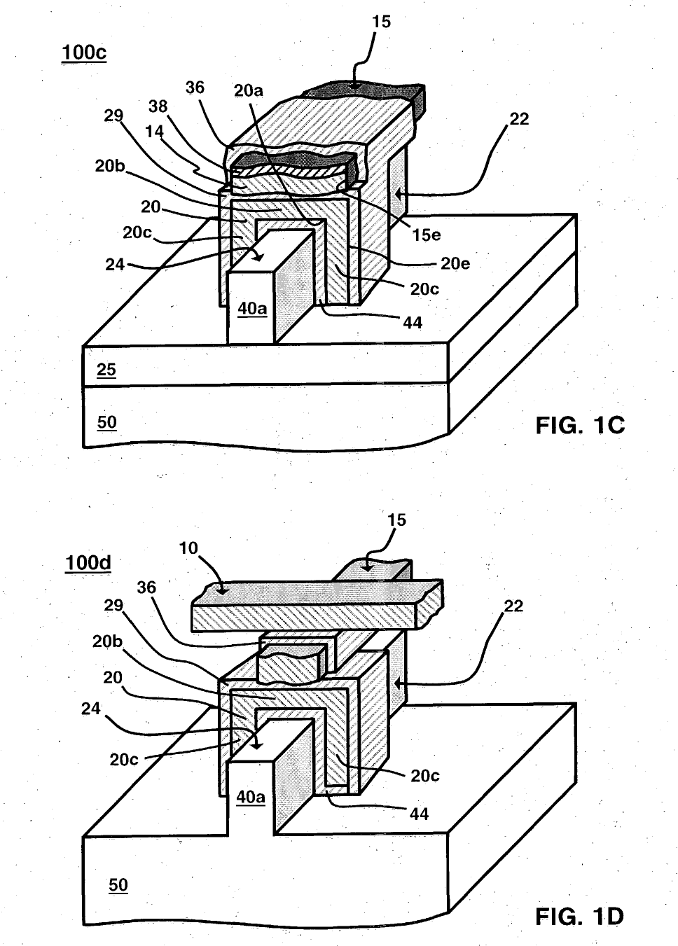

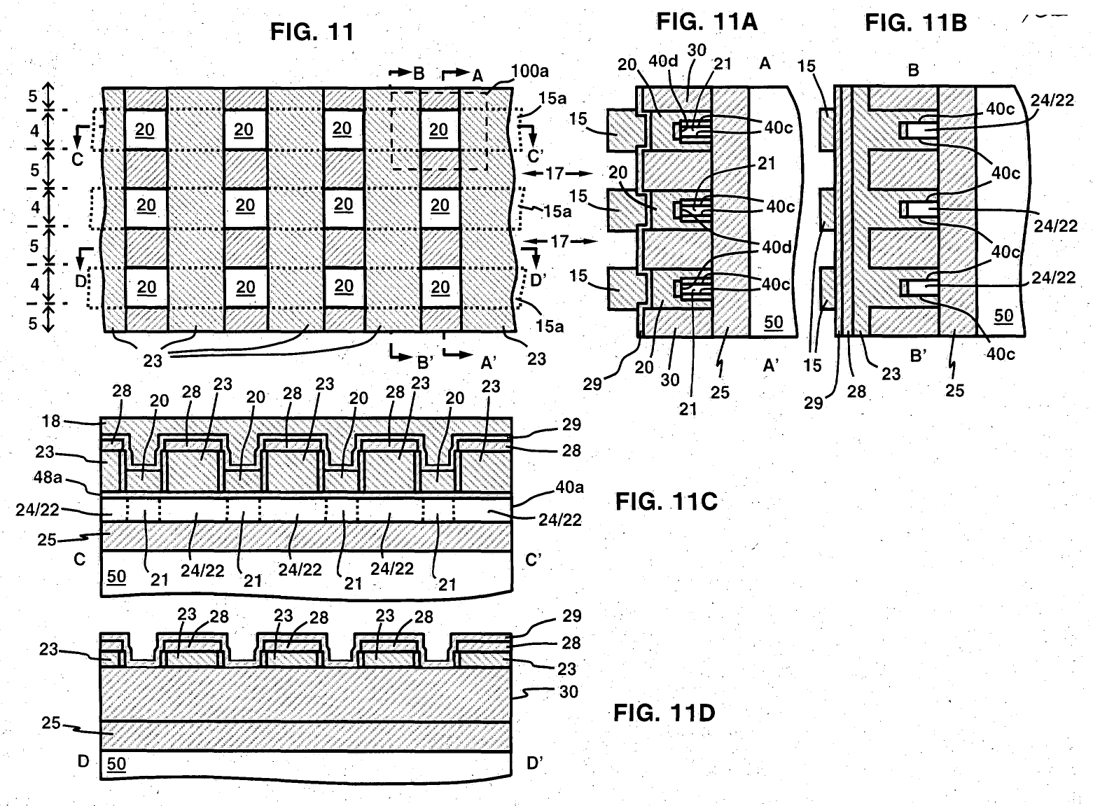

Referring to FIG. 1A, there is shown cross sectional view of a single transistor nonvolatile memory cell in accordance with the first embodiment of the present invention. Memory cell 100a comprises a substrate 50, which can be a semiconductor such as silicon of a first conductivity type (p-type hereinafter) with a doping level in the range between about 1×10¹⁵ atoms/cm³ to about 5×10¹⁷ atoms/cm³. On the substrate 50 is an insulating layer 25 such as silicon oxide, silicon sulfide or other dielectrics well known in the art. The thickness of the insulating layer 25 can be on the order of about 0.2 micrometer (μm) to about 4 μm. A silicon block 40a is disposed over and insulated from the substrate 50 by the insulating layer 25 to form an active region for the memory cell 100a. The silicon block 40a can be a substantially rectangular shaped structure, or a trapezoidal shaped structure, having a height (or thickness) in the range of about 0.1 μm to about 1 μm and a width in the range of about 0.05 μm to about 0.8 μm. The silicon block 40a has two sidewalls 40c, a top 40d, and a bottom 40e, wherein the sidewalls 40c can be substantially perpendicular to the surface of insulating layer 25, and wherein the top 40d is substantially parallel to the surface of insulating layer 25. An electrically conductive floating gate 20 is disposed over and insulated from a portion of the silicon block 40a by a first insulating layer 44, which can be with thickness on the order of 50 to 400 angstrom (Å) and can be made from silicon dioxide (hereinafter “oxide”), silicon nitride (hereinafter “nitride”), silicon oxynitride (hereinafter “oxynitride”) or insulating materials with high dielectric constant (such as aluminum oxide, hafnium oxide, zirconium oxide etc). The floating ate 20 has a folded structure comprising two vertical sections 20c (first and second sections) each disposed laterally adjacent to and insulated from a portion of one of the sidewalls 40c of the silicon block 40a, and a horizontal section 20b (third section) disposed over and insulated from a portion of the top of the silicon block 40a. The horizontal section 20b joins with each of the vertical sections 20c at a corner 20a and having a concave shape surface surrounding a portion of the silicon block 40a. Moreover, a bottom portion 20f of each of the vertical sections 20c of the floating gate 20 is disposed over and insulated from the substrate 50 by the insulating layer 25. The horizontal section 20b of the floating gate 20 can be with thickness on the order of 200 to 3000 angstrom, whereas the vertical section 20c of the floating gate 20 can have a thickness on the order of 200 to 5000 angstrom. The floating gate 20 can have a length 20d, defined along the length direction of the silicon block 40a, on the order of about 0.02 μm to about 0.8 μm. Disposed over and laterally adjacent to the floating gate 20 is a second layer 29 of insulating material, on the order of 50 to 400 angstrom of thickness. The second layer 29 can be made from oxide, nitride, oxynitride, aluminum oxide, hafnium oxide, zirconium oxide or a combination of these materials, such as oxide/nitride/oxide composite film. Disposed over the second insulating layer 29 is a control gate 15, which can be a heavily doped polycrystalline silicon (hereinafter “polysilicon”), low resistivity interconnect material such as silicide, or a refractory metal. The control gate 15 can be with a thickness on the order of 400 to 4000 angstrom. A first region 24 and a second region 22 are provided in the uncovered portions of the silicon line block 40a. A channel region 21 (shown in FIGS. 11A and 11C) is provided in the silicon blocks 40a and is disposed adjacent to the surfaces of the top 40d and the sidewalls 40c of a portion of the silicon blocks 40a in between the first and second regions 24/22. The channel current flows along a direction parallel to the direction as defined in the channel length 20d. The first and second regions can be heavily doped regions of a second conductivity type (n-type hereinafter) with a doping level in the range of about 1×10¹⁸ atoms/cm to about 5×10²¹ atoms/cm³. The first region 24 forms the source region of the memory cell, whereas the second region 22 thus defined forms the drain region of the memory cell.

Memory cell 100b shown in FIG. 1B provides a second embodiment of the present invention. The cell 100b comprises similar provisions as defined in the memory cell 100a in FIG. 1A except with a major difference on the substrate where the silicon block 40a is formed onto. In memory cell 100a the silicon line block 40a is disposed over and insulated from the substrate 50 by the insulating layer 25, whereas in memory cell 100b the silicon line block 40a is formed in the substrate 50. An additional difference is on the insulation of the floating gate 20 to the Substrate 50 for the memory cell 10b. Referring to FIG. TB, without the insulating layer 25 as provided in the memory cell 100a, the memory cell 100b provides a bottom portion 44b of the first insulating layer 44 to insulate the vertical sections 20c of the floating gate 20 to the substrate 50. As a result of these differences, the method making these two cells are fundamentally different from each other, as will be described in a greater detail hereinafter.

Memory cell 100c shown in FIG. 1C provides a third embodiment of the present invention. The cell 100c comprises similar provisions as defined in the memory cell 100a in FIG. 1A except with a major difference on the method of making the memory cells. In memory cell 100c, the control gate 15 comprises a polysilicon layer 14 and a metalized polysilicon layer 38 with the control gate edge 15e be substantially aligned to the floating gate edge 20e using a self-aligned process method, which will be described in a greater detail hereinafter.

The memory cells 100a, 100b, 100c can be programmed by, for example, injecting electrons onto the floating-gate 20 using the CHEI (Channel-Hot-Electron Injection) mechanism well-known in the art. This can be done, for example, by applying a voltage (e.g. 3V) to the control gate 15, which couples enough voltage into the floating gate 20, to turn on the channel region 21 while the first region (or source) 24 is at ground and the second region (or drain) 22 is at a higher voltage (e.g. 3.3V). The electrons in the channel region flow from the first region 22 to the second region 24 in a path parallel to the floating gate, where a number of the electrons become heated and are injected onto the floating gate. The folded floating gate structure in the present invention permits a higher CHEI efficiency than that in the conventional memory cells as aforementioned (e.g. U.S. Pat. No. 4,957,877). This is due to a strong fringing electric field emerging from the floating gate 20 nearby its folded corner 20a to the channel 21 nearby the same region. More specifically, the electric field for a folded floating gate cell is in a three-dimensional form having its field lines emerging from each of the three sections. The field lines end at the top and the sidewalls surfaces on the silicon block, with an additional fringing component at the corners 20a. The unique field distribution is due to the electrostatic effect of a concave-shaped electrode (i.e. folded floating gate) on another electrode (i.e. channel in silicon block) surrounded by the concave-shaped one. This field effect is unique and provides various advantages on PROGRAM operation using the. CHET. First, it results in a stronger inversion layer in the channel 21 along the folded corner 20a, and hence results in a higher concentration on channel carriers (e.g. electrons) used for the CHEI. In addition, it results in a stronger field in the direction favorable to electrons be injected into the floating gate 20. Last, it suppresses the drain-to-source punch-through phenomenon, which is a scaling limiter as scaling down the channel length, as aforementioned. ERASE operation can be done by pulling electron-charges out of the floating gate via Fowler-Nordheim tunneling mechanism. The control gate 15 can be at a negative voltage (e.g. −3.3V), whereas the first region 24 can be at a high voltage (e.g. 4 to 6V) and the second region 22 can be left floating or at ground. For ERASE operation, the folded floating gate structure enhances the electric field nearby the folded corners 20a in an overlapping region between the first region 24 and the floating gate 20. The effect of the folded floating gate structure on ERASE operation results in a faster erase due to the stronger electric field or a lower erase voltage for a given erase time.

Memory cell 100d shown in FIG. 1D provides a fourth embodiment of the present invention. The cell 100d comprises similar provisions as defined in the memory cell 100b in FIG. 1B except with additional components added in, namely, a third insulating layer 36 and a tunneling gate 10. Referring to the memory cell 10d, the tunneling gate 10 is disposed over and insulated from the control gate 15 by the third insulating layer 36 having a thickness permitting charges transporting through via a quantum mechanical tunneling mechanism. The tunneling gate overlaps with the control gate at an overlapping region, where at least a portion of the floating gate is disposed thereunder. The tunneling gate 10 can be a heavily doped polycrystalline silicon, and a low resistivity interconnect material such as silicide, or a refractory metal, and is with a thickness on the order of 500 to 4000 angstrom. The third insulating layer 36 can be oxide, nitride, oxynitride, materials with high dielectric constant (such as aluminum oxide, hafnium oxide, zirconium oxide etc.) or a combination of these materials, and is on the order of 30 to 200 angstrom in thickness.

The dimensions of the cells in accordance with the present inventions are closely related to the design rules of a given generation of process technology. Therefore, the foregoing dimensions on cells and on regions defined therein are only illustrative examples. For the memory cell 10d, in general, however, the dimension of the memory cell is such that charges emanating from the tunneling gate 10 are allowed to transport through the third insulator 36 through tunneling mechanism such as direct tunneling, which typically occurs at a low voltage (e.g. 3.3V or lower), or through the Fowler-Nordheim tunneling mechanism, which occurs at a higher voltage (e.g. 6V). Furthermore, the dimension on thickness of the control gate region 15 is such that the same group of charges that transport through the insulator 36 can further transport through it and be collected by the floating gate 20 at a good percentage on collection rate, which typically ranges from about 1% to tens of percent, to the charges from tunneling gate 10.

Method of Manufacturing and Memory Cell Operations

One of various objectives of this invention is to introduce new cell architectures for nonvolatile memory cell. Another one is to demonstrate the manufacturing method of the memory cells and array.

In manufacturing semiconductor floating gate memory cells and arrays, one of the problems has been the alignment of the various components such as source, drain, control gate, and floating gate. As the design rule of integration of semiconductor processing decreases, reducing the smallest lithographic feature, the need for precise alignment becomes more critical. Alignment of various parts also determines the yield of the manufacturing of the semiconductor products. Therefore, memory cells manufactured using alignment techniques (i.e. using “non-self aligned” methods) encountered issues on cell manufacturability and scalability.

Self-alignment is well known in the art and has the advantage addressing the aforementioned issues in manufacturing. Self-alignment refers to the act of processing one or more steps involving one or more materials such that the features are automatically aligned with respect to one another in that step processing. Accordingly, self-alignment minimizes the number of masking steps necessary to form memory cell structures, and enhances the ability to scale such structures down to smaller dimensions.

The present invention further provides self-alignment techniques and manufacturing methods to form memory cells and a memory cell array formed thereby. The memory cells utilize a unique memory cell architecture permitting significant cell size reduction with enhancement on cell performance.

First Embodiment

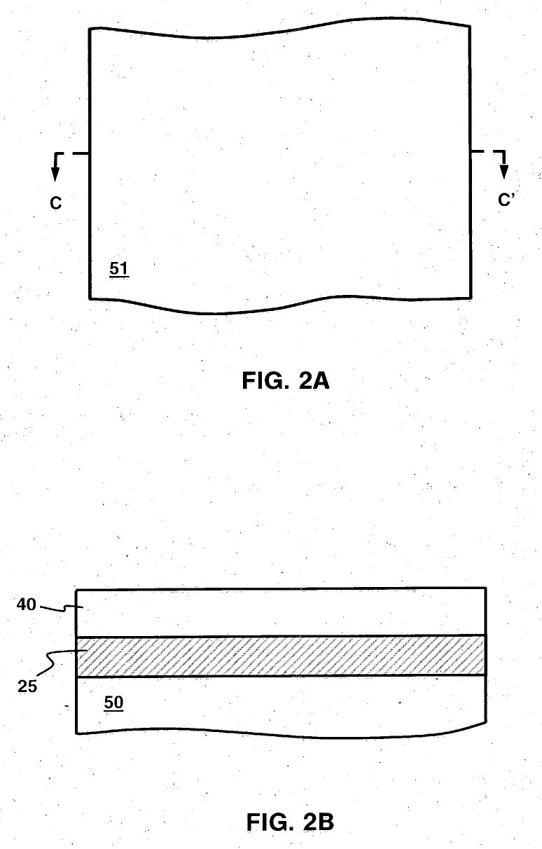

Referring to FIG. 2A there is shown a top plan view of a semiconductor bulk material 51, which can comprise an insulating layer 25 sandwiched in between a semiconductor layer 40 and a semiconductor substrate 50, and is used as the staring material for forming memory cells and array in accordance with the first embodiment of this invention. A cross-sectional view of the structure thus described is shown in FIG. 2B, wherein the semiconductor layer 40 is preferably of p-type silicon and can be formed by well-known techniques such as ion implantation, which introduces impurity into the layer 40.

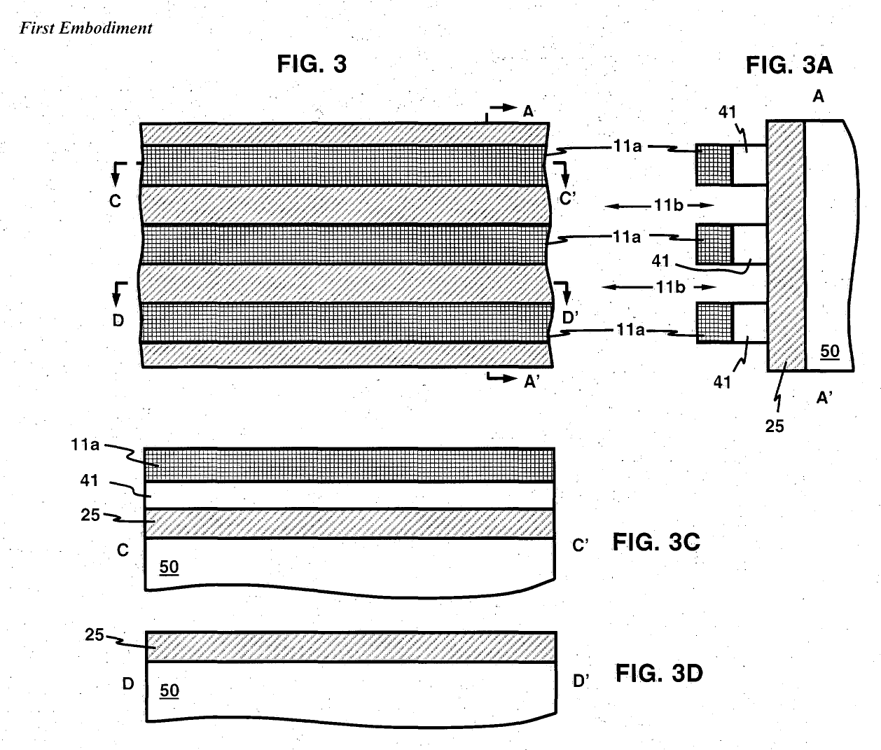

With the structure shown in FIG. 2B, the structure is further processed as follows. An insulator 11 is formed on top of the silicon layer 40 with thickness preferably at about 800 to about 1500 Å. The insulator can be, e.g., nitride deposited by employing conventional Low Pressure CVD or LPCVD deposition process. The insulator can be in single layer form or in composite layers form with other types of insulator (e.g. combination of oxide and nitride). Next, a photo-resistant material (“photo-resist” hereinafter) on the structure surface is suitably applied followed by a masking step using conventional photo-lithography technique to selectively remove the photo-resist leaving a plurality of photo-resist line traces oriented in a first direction over the nitride layer 11. The process is continued by etching the exposed nitride layer 11 followed by a silicon etch to remove the exposed silicon layer 40 until the buried insulating layer 25 is observed, which acts as an etch stop. The portions of layers 11 and 40 still underneath the remaining photo-resist are unaffected by this etch process. This step forms a plurality of nitride traces 11a orientated in the first direction (or “row” direction) with each pair of them spaced apart by a stripe of trench 11b. The width of the nitride traces 11a and the distance between adjacent traces 11b can be as small as the smallest lithographic feature of the process used. The remaining photo-resist is then removed using conventional means. The top plan view of the resulting structure is illustrated in FIG. 3 with nitride line blocks 11a interlaced with the trench stripes 11b. The process steps also forms a plurality of silicon line blocks 41 with each of them formed under and self-aligned to one of the nitride blocks 11a. FIG. 3A illustrates the cross-sectional view along line AA′ to illustrate the formation of the silicon line blocks 41. FIGS. 3C and 3D are cross-sectional view for structure along lines CC′ and DD′ in FIG. 3 and are used to collectively illustrate the structure at this process step along these two lines. It should be readily appreciated by those of ordinary skill in the art that the silicon line blocks 41 need not be a continuous line along the row direction but can be divided into spaced apart segments of blocks through proper defining the photo-resist patterns.

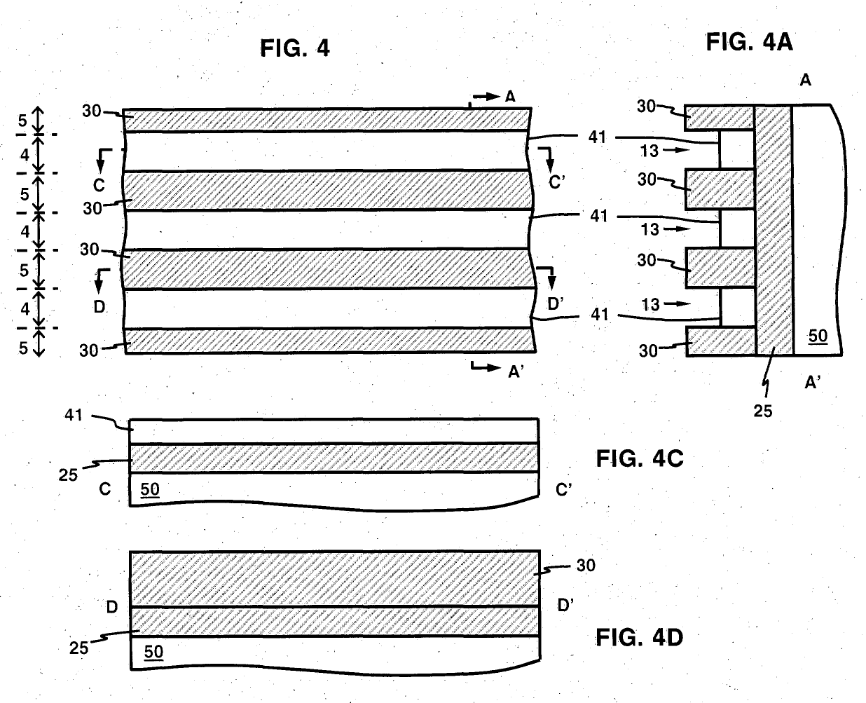

The process is continued by forming a relative thick oxide layer (not illustrated) to fill the trench stripes 11b using well-known techniques such as conventional LPCVD. The oxide is then selectively removed to leave oxide blocks 30 in region within the trench stripes 11b. The preferable structure is with the top surface of the oxide blocks 30 substantially co-planar with the top surface of nitride blocks 11a. This can be done by, for example, employing a chemical-mechanical polishing (CMP) process to planarize the thick oxide followed by an RIE (reactive ion etch) using nitride blocks 11a as an etching stopper. An optional oxide over-etching step follows if necessary to clear any oxide residue on the nitride blocks 11a. Thereby, the process leaves oxide only in trench stripes 11b to form oxide blocks 30 self-aligned to the trench stripe openings 11b. The process is then followed by an etching step removing the nitride blocks 11a (e.g. using hot phosphoric acid). This forms a plurality of first semi-recessed trenches 13 and traces of oxide blocks 30 oriented in the first direction. The step also forms spaced-apart silicon line blocks 41, which forms the active regions 4 of the memory cells and are generally parallel to one another and extend in the first direction, with an oxide block 30 as an isolation region 5 between each pair of adjacent silicon line blocks 41. The top plan view of the resulting structure is illustrated in FIG. 4 with silicon line blocks 41 interlaced with the oxide line blocks 30. The cross-sectional views of the resulting structure are collectively illustrated in FIGS. 4A, 4C, and 4D.

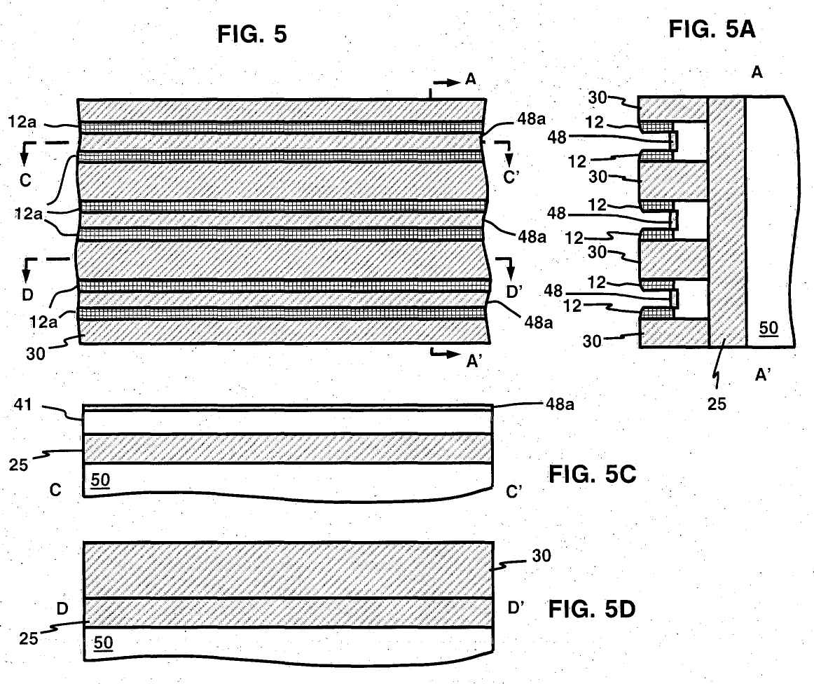

The structure is further processed by forming a plurality of nitride spacers 12 in the semi-recessed trenches 13. The formation of spacers is well known in the art, and includes depositing a material over the contour of a structure, followed by an anisotropic etch process (e.g. RIE), whereby the material is removed from horizontal surfaces of the structure, while the material remains largely intact on vertically oriented surfaces of the structure. To form nitride spacers 12, a layer of nitride is deposited over the structure, followed by an anisotropic nitride etch, which removes the deposited nitride except for spacers 12 inside the semi-recessed trenches 13. Each of the nitride spacers 12 is formed along a sidewall of one of the oxide blocks 30 and can have a width about 200 to about 1000 Å pending on the opening width of the semi-recessed trenches 13 and the generation of the technology employed. The nitride etch step uses the silicon in the silicon line blocks 41 as the etch stop; Therefore at the end of the etch, a pair of spaced apart nitride spacer line traces 12a is formed within each of the semi-recessed trenches 13 with a portion of the silicon line blocks 41 exposed therebetween. The structure is further processed to form oxide regions 48 self-aligned to the nitride spacers 12 (shown in FIG. 5A). This can be done by growing oxide on the exposed portion of silicon line blocks 41 using thermal oxidation with nitride spacers 12 as an oxidation mask. The oxidation step further forms a plurality of oxide line traces 48a with each of them self-aligned to and sandwiched between a pair of the nitride spacer line traces 12a. The oxide region 48 can be with a thickness on the order of about 100 Å to about 400 Å. The top plan view of the resulting structure is illustrated in FIG. 5 with nitride-spacer line traces 12a interlaced with the oxide line traces 48a of the oxide region 48 and with the oxide line blocks 30. The cross-sectional views of the resulting structure are collectively illustrated in FIGS. 5A, 5C, and SD.

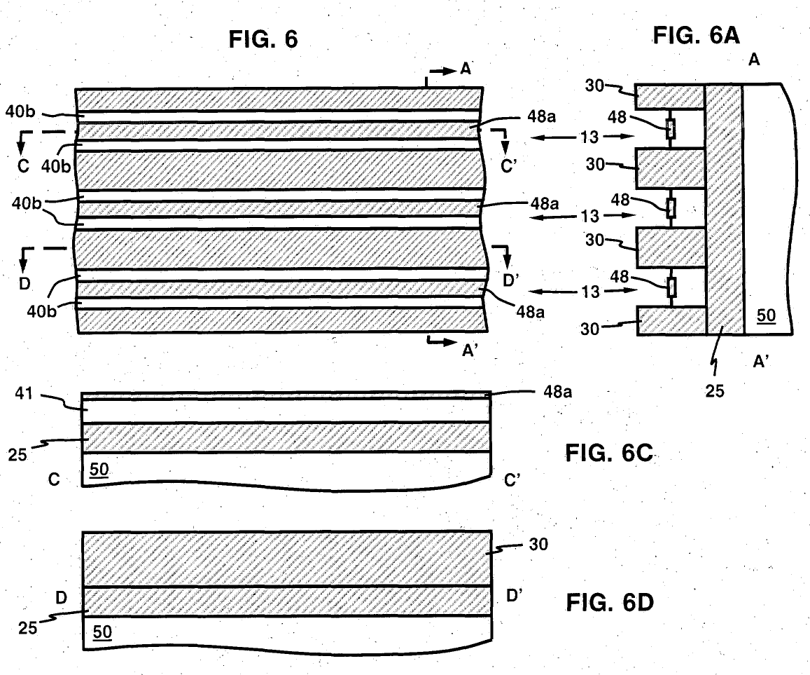

A nitride etch process follows (e.g. etch in hot phosphoric acid) to remove nitride spacers 12 and the nitride spacer line traces 12a in the semi-recessed trenches 13 (FIG. 6A). The surface of the silicon line blocks 41 originally covered by the nitride spacers is thus exposed to form a plurality of stripes 40b on the silicon line blocks 41 in the structure, as shown in FIG. 6. Within each of the semi-recessed trenches 13, a pair of the exposed silicon stripes 40b is spaced-apart from each other with one of the oxide line traces 48a divided therebetween. The cross-sectional views of the resulting structure are collectively illustrated in FIGS. 6A, 6C, and 6D.

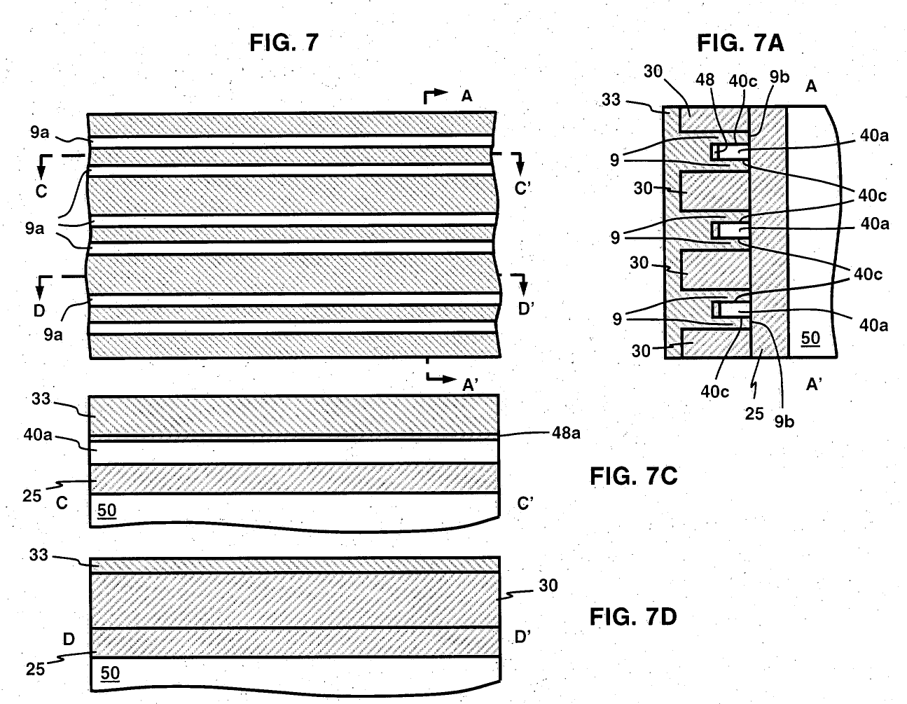

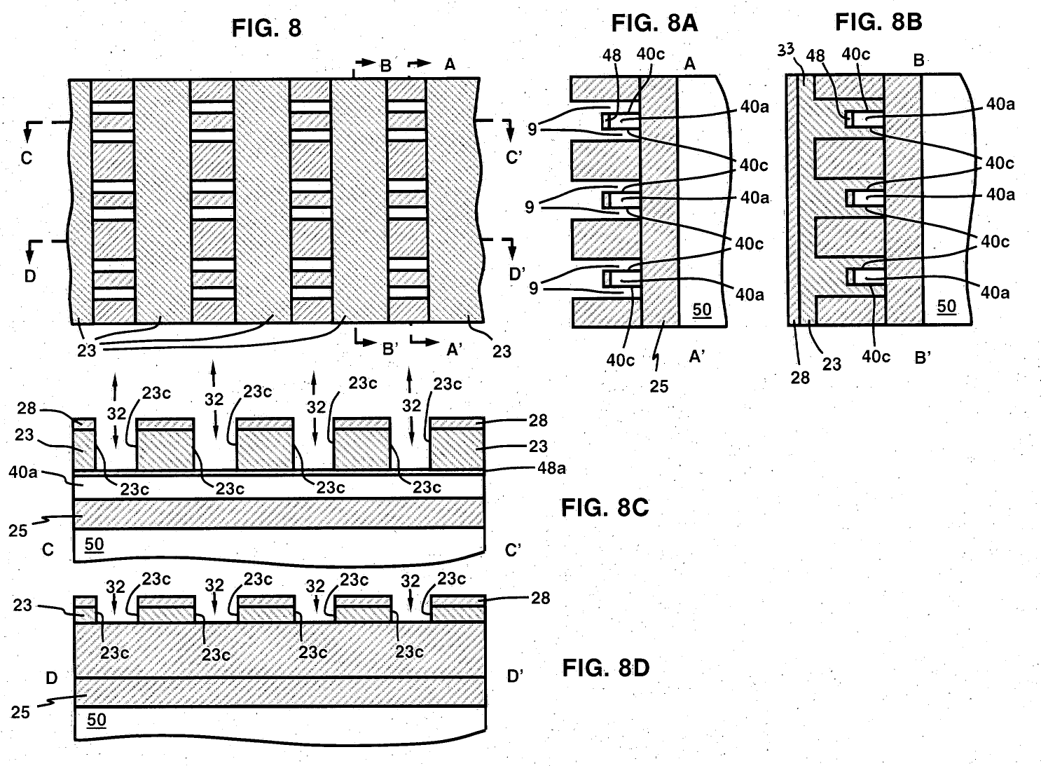

The structure is further processed by etching the exposed silicon in the stripes 40b (with the buried insulator 25 as the etch stop) to form a plurality of trench traces 9a oriented in the first direction (shown in FIG. 7). The etching can be done by using an anisotropic etching process (such as the well-known RIE) to selectively etch the exposed silicon without attacking the oxide regions 48 and oxide blocks 30. This etching step forms a plurality of silicon block stripes 40a and a plurality of first trenches 9 with each of the first trenches 9 formed in between one of the oxide blocks 30 and one of the silicon block stripes 40a (shown in FIG. 7A). Due to the nature of RIE etching process, each of the silicon block stripes 40a thus formed can have a cross section being generally rectangular shaped or trapezoidal shaped. A first layer of electrically conductive material 33 such as polysilicon is deposited over the structure using, for example, conventional LPCVD technique with polysilicon film doped in-situ or by a subsequent ion implantation. The polysilicon layer thus formed is heavily doped with impurity of a second conductivity type at a doping level in the range of about 1×10⁸ atoms/cm³ to about 5×10²¹ atoms/cm³. The polysilicon layer 33 is with a thickness thick enough to fill the first trenches 9 and can be on the order of, for example, about 700 Å to 3000 Å. Preferably, the topography of the polysilicon layer 33 thus formed is substantially planar, and an optional planarization process (i.e. CMP) can be used for achieving the planar topography. The electrically conductive material 33 fills each of the first trenches 9 and is in direct physical contact with the sidewalls 40c of each of the silicon block stripes 40a, as shown in FIG. 7A. It should be noted that polysilicon is chosen for material 33 for illustration purpose (due to process simplicity). In general, any other materials that can be used as an impurity diffusion source, having a low sheet resistance, a good trench-gap filling capability, and stable material property at high temperature (e.g. 1000° C.) can be employed instead. For example, a metalized polysilicon layer such as polysilicon with tungsten-polycide atop can be employed for the conductive layer 33 by using well-known CVD technique. Tungsten-polycide has a sheet-resistance typically about 5 to 10 Ohms/square, and is significantly lower than that in an un-metalized heavily doped polysilicon, whose sheet-resistance is typically about 100 to 300 Ohms/square. As will be illustrated in FIG. 8, the material 33 is used to form source lines, and a lower sheet resistance is desirable as it has the advantage on reducing the source line resistance, and hence reducing the memory access time in a read operation. The top plan view of the resulting structure is shown in FIG. 7 and the cross-sectional views of the resulting structure are collectively illustrated in FIGS. 7A, 7C, and 7D. Those of skill in the art will recognize that the silicon block stripe is connected to the silicon block of a memory cell. Thus, the term silicon block stripe, silicon line block and silicon block may be used interchangeably.

A thick insulating layer 28 with thickness on the order of about 500 Å to 1000 Å is formed over the polysilicon layer 33. The insulating layer 28 can be in a single layer film made of oxide or nitride, or can be in a composite layers form comprising a combination of oxide and nitride films. For illustration purpose, here oxide is chosen as example for the insulating layer 28. Next, a photo-resist is formed over the oxide layer 28 followed by a masking step using conventional photo-lithography technique to selectively remove the photo-resist leaving a plurality of photo-resist stripes over the oxide layer 28 and oriented in a second direction substantially perpendicular to the first direction (for defining the Source Lines/Bit Lines or Source Lines/Drain Lines). The process is continued by using an anisotropic etch process, such as RUE, to remove the exposed oxide layer 28 followed by a polysilicon etch to remove the exposed polysilicon layer 33 thereunder. The etch process continues until the buried insulating layer 25 is observed, which acts as an etch stop. This etch forms spaced apart Source Lines/Bit Lines (SL/BLs) 23, which are generally parallel to one another and extend in the second direction, with a trench stripe 32 between each pair of adjacent SL/BLs 23. The portions of layers 28 and 33 still underneath the remaining photo-resist are unaffected by this etch process. The portions of silicon block stripes 40a in the trench stripe regions 32 are uncovered by the photo-resist but are protected by the oxide regions 48, and hence are not affected by this etch process as well. The space between adjacent SL/BLs 23 and the width of each SL/BLs 23 can be as small as the smallest lithographic feature of the process used. This step also re-exposes the portion of first trenches 9 in the trench stripes regions 32 to the air (FIG. 8A). The remaining photo-resist is then removed using conventional means. The top plan view of the resulting structure is illustrated in FIG. 8 with SL/BLs 23 interlaced with the trench stripes 32. FIG. 8A illustrates the cross-sectional view along line AA′ to illustrate the complete removal of the polysilicon layer 33 in first trenches 9 in one of the trench stripe regions 32. The sidewalls 40c of silicon block stripes 40a in the trench stripe regions 32 are exposed to the air at this process step. FIG. 8B illustrates the cross-sectional view along line BB′, which corresponds to the SL/BL regions 23 in FIG. 8. The sidewalls 40c of the silicon block stripes 40a are electrically contacted to the polysilicon 33 of each of the SL/BLs 23. FIGS. 8C and 8D are cross-sectional view for structure along lines CC′ and DD′ in FIG. 8 and are used to collectively illustrate the structure at this process step along these two lines. The sidewalls 23c of each of the SL/BLs 23 are shown exposed to the air in both FIGS. 8C and 8D.

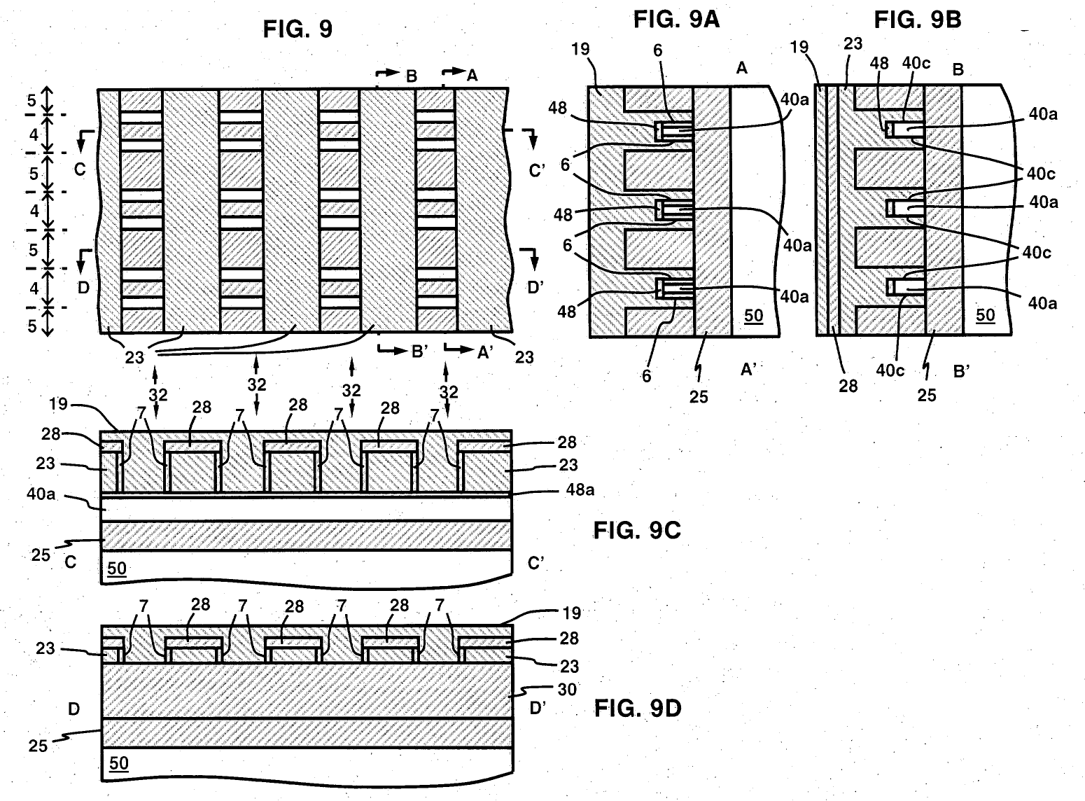

The process is continued by forming insulator such as oxide on the exposed portion of silicon and polysilicon regions described in FIGS. 8A-8D. This can be done by, for example, using conventional thermal oxidation technique to form oxide film with thickness on the order of about 50 Å to about 200 Å, and is preferably about 80 Å. The oxidation step forms oxide regions 6 on the sidewalls 40c of the silicon block stripes 40a in the trench stripes regions 32 (FIG. 9A). Within an active region 4 in each of the trench stripe regions 32, there is a pair of oxide regions 6 joining with the oxide regions 48 therein to form the first insulating layer region 44 (shown in FIG. 1A). The step thus form a plurality of insulating layer regions 44, with each of the insulating layer region 44 disposed laterally adjacent to and over one of the silicon blocks 40a in the trench stripe regions 32. The same oxidation also forms oxide regions 7 on the sidewalls 23c of the SL/BLs 23 (FIGS. 9C-9D). Each of the oxide regions 7 joins with one of the oxide regions 28 in forming an insulating layer that is disposed laterally adjacent to and over one of the SL/BLs 23. During this thermal process, impurity in the polysilicon 33 of each of the SL/BLs 23 out-diffuse into the silicon blocks 40a in portions having the sidewalls 40c contacted by the SL/BLs 23. The portion of silicon blocks where impurity diffuses into forms the first and the second regions 24/22 of the memory cells. The SL/BLs 23 thus formed extend continuously across the isolation and active regions 5/4, and thus electrically connect all the first regions 24 together and all the second regions 22 together for each column of memory cells extending in the second direction.

Thereafter, a second polysilicon layer 19 is formed over the structure by, for example, using conventional Low-Pressure-Chemical-Vapor-Deposition (LPCVD) technique with polysilicon film doped either in-situ or through a subsequent ion implantation. The second polysilicon layer 19 can be with thickness from about 500 Å to about 1000 Å, and is to be used to form the floating-gate region 20 of the memory cell. The second polysilicon layer 19 thus formed is disposed over the trench stripe regions 32 and over the SL/BL regions 23. For the polysilicon layer 19 over the trench stripe regions 32, the polysilicon 19 fills each of the trenches stripes and is disposed over and laterally adjacent to each of the silicon blocks 40a with oxide regions 6 and 48 insulating the polysilicon 19 from each of the silicon blocks 40a, as shown in FIG. 9A. For the polysilicon layer 19 over the SL/BL regions 23, the polysilicon layer 19 is formed over and insulated from each of the SL/BLs 23 by the oxide layer 28, as shown in cross-sectional view in FIG. 9B. The second polysilicon layer 19 in each of the trench stripes 32 is formed laterally adjacent to and insulated from the SL/BLs 23 by the oxide regions 7, as shown in the cross-sectional view in FIG. 9C. The topography of the second polysilicon layer 19 thus formed is substantially planar. The top plan view of the resulting Structure is shown in FIG. 9 and the cross-sectional views of the resulting structure are collectively illustrated in FIGS. 9A, 9B, 9C; and 9D.

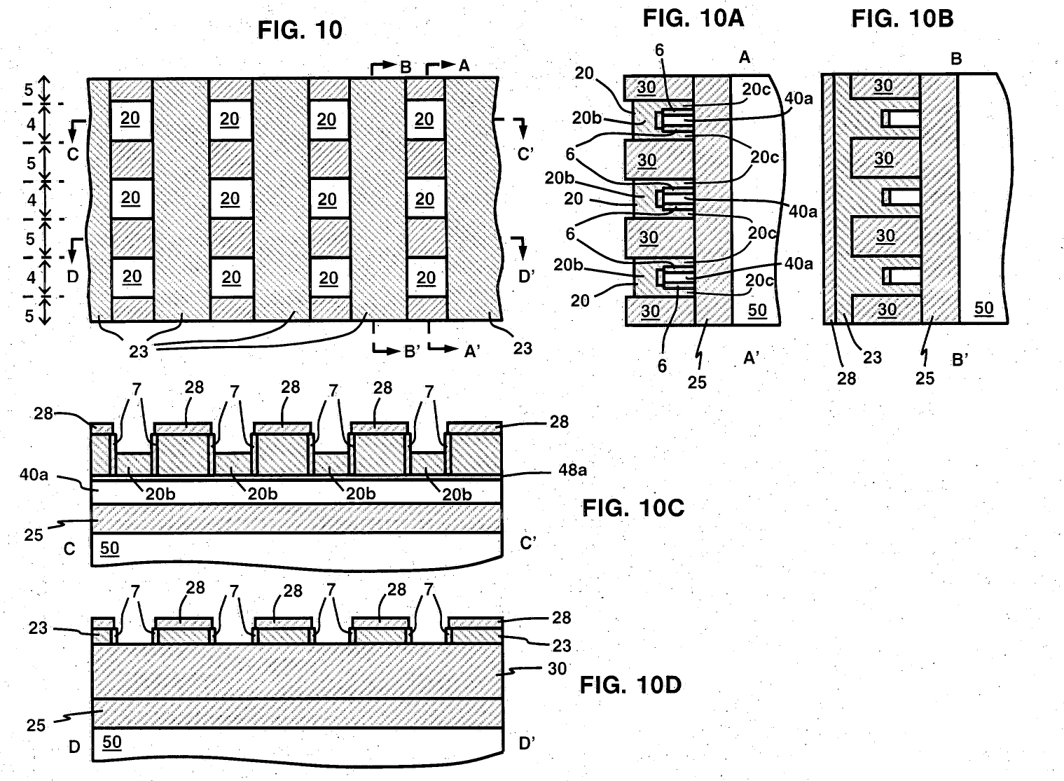

A polysilicon etch follows thereafter to remove the second polysilicon layer 19 on the oxide blocks 30 in the trench stripe regions 32. The portion of the polysilicon 19 on the oxide insulator 28 is also removed in the same etch leaving the polysilicon layer 19 only within the trenches 9 in the trench stripe regions 32. This can be done by, for example, using conventional anisotropic etch technique such as RIE. A proper over-etch can be optionally applied to the structure to ensure the second polysilicon 19 is completely removed from the top surfaces of the oxide blocks 30 and of the oxide layer 28. This forms the self-aligned floating-gate 20 with folded architecture in each of the memory cells. The exposed surface of the remaining polysilicon 19 is substantially co-planar with or slightly below the top surface of oxide blocks 30, as shown in FIG. 10A. The top plan view of the resulting structure is shown in FIG. 10. An array of floating gates 20 is shown in FIG. 10, wherein each of the floating gates 20 thus formed comprises a pair of vertical sections 20c (first and second sections), each laterally adjacent to a portion of one of the sidewalls of one of the silicon block 40a, and a horizontal section 20b (third section) over a portion of the top of the one silicon blocks 40a. The cross-sectional views of the resulting structure are collectively illustrated in FIGS. 10A, 10B, 10C, and 10D.

The structure is further processed by forming a second insulating layer 29 such as oxide with thickness on the order of about 50 Å to 300 Å using conventional deposition technique or thermal oxidation process. The second insulator 29 can also be formed in composite layers comprising more than two different dielectrics (e.g. oxide-nitride-oxide tri-layers). For process simplicity, an oxide layer of HTO (high temperature oxide) is chosen here as the insulating layer 29 for illustration purpose. Next, an electrically conductive layer 18 with thickness on the order of about 500 to 4000 Å is deposited over the structure. The layer 18 can be made of, for example, polysilicon, W-polycide or metals, and is to be used to form the control gate block 15 of the memory cells 100a. For illustration, polysilicon is chosen here for the layer 18 with the topography preferably planar. An optional metalized polysilicon (not shown) can be deposited on the polysilicon to reduce its sheet resistance using well-known Chemical-Vapor-Deposition (CVD) technique. Thereafter, a photo-resist is formed over the polysilicon layer 18 followed by a masking step using conventional photo-lithography technique to selectively remove the photoresist leaving a plurality of photo-resist stripes over the polysilicon layer 18 and oriented in the first direction. Each of the photo-resist stripes is properly aligned to one of the active regions 4. The process Is continued by using an anisotropic etch process, such as RIE, to remove the, exposed polysilicon layer 18 until the oxide layer 29 is observed, which acts as an etch stop. The portions of polysilicon layer 18 still underneath the remaining photo-resist are unaffected by this etch process. This etching step forms a plurality of control gates 15 each disposed over and insulated from one of the floating gates 20. The etch also forms a plurality of spaced apart word lines 15a, which are generally parallel to one another and extend in the first direction with a trench stripe 17 between each pair of adjacent word lines 15a (FIG. 11). Each of the word lines 15a extends continuously across the SL/BLs 23 and the trench stripe regions 32 to connect together a row of the control gates IS in that row of memory cells. The space between adjacent word lines 15a and the width of each of the word lines 15a can be as small as the smallest lithographic feature of the process used. The remaining photo-resist is then removed using conventional means. The top plan view of the resulting structure is shown in FIG. 11, wherein the border of one of the memory cells 100a is shown. The memory cells 100a are arranged along with the floating gates 20 in an array of rows extending in the first direction and columns in the second direction. In each of the silicon line blocks 40a of the resulting structure, the portions of 40a under the SL/BLs 23 correspond to the first and second regions 24/22 of the memory cells 100a, as shown in FIG. 11C. Each of the first and second regions 24/22 is electrically contacted by the SL/BLs 23 through the sidewalls 40c of each of the silicon blocks 40a, as shown in FIG. 11B. Each of the channel region 21 is defined in between a pair of the first and second regions 24/22, as shown in FIG. 11C, and are formed under the surfaces of the top 40d and sidewalls 40c of the silicon blocks 40a, as shown in FIG. 11A. The memory cell is a three-dimensional structure. During cell operations, the channel carriers flow from the first region 24 to the second region 22 along the channel in a direction orthogonal to that of FIG. 11A.

The cross-sectional views of the resulting structure are collectively illustrated in FIGS. 11A, 11B, 11C, and 11D.

The structure can be further processed by following conventional backend process steps (not illustrated). These steps include, for example, forming an insulating material (e.g. BP TEOS) to cover the structure, followed by a contact masking step to define contact openings to make proper electrical connections to the electrodes in a memory array. The contact openings are then filled with conductor metal contacts by metal deposition, planarization, and etch-back. Finally, metal lines are formed to connect contacts followed by forming a passivation and bonding pads atop the structure.

The foregoing method and memory cell array formed thereby have several advantages. First, as shown in the cross-sectional view along the row direction (FIG. 11C), the first and second regions 24/22 of each memory cell are formed to self-align to one of the source/drain lines 23, which can be formed in the smallest feature size on width for a line feature of a process technology. Second, along the same cross-section, the floating gates 20 are formed in between and self-aligned to a pair of the source/bit lines 23, which can be formed in the smallest feature size on spacing between adjacent line features of a process technology. Third, in the cross-section along the column direction (FIG. 11A), each of the floating gates 20 is formed self-aligned and spaced apart from an adjacent one by one of the insulator blocks 30, which can be formed in the smallest feature size of a process technology. Fourth, the floating gate 20is folded around the silicon block 40a to form a three-dimensional fringing field from the sidewalls of the vertical sections. The fringing field can enhance the control of the floating gate on the channel surface potential and hence suppress the drain-to-source punch-through as drain is at a high bias for CHEI operation. Thereby, the folded floating gate architecture permits a cell scaling along the Length direction. Moreover, the program efficiency is greatly enhanced due to the denser channel carriers flowing adjacent to the folded corner and due to the stronger sidewall fringing-field. In conventional unfolded nonvolatile memories, the electrons in the channel region flow in a plane parallel to the substrate, where a relatively small number of the electrons become heated and are injected onto the floating gate. The estimated program efficiency (i.e. number of electrons injected compared to total number of electrons) is estimated at about 1/10000. However, because of the folded corner portion of the channel region here, the denser channel carriers and the stronger corner fringing field enhance the program efficiency of the memory cells to be closer to 1/1000, which is almost one order of magnitude higher than the conventional one. Fifth, the present invention presents cell structures with wider channel, permitting cell scaling without sacrificing the channel current. This is because the channel current is linearly proportional to the channel width. For memory cells of the present invention, other than the plane component observed in conventional memory cells, the cells also provide additional channel components contributed from the sidewalls 40c substantially perpendicular to the substrate, thus increasing the effective channel width without enlarging the cell Width and area. Finally, the memory structure of the present invention is formed by using a relatively low number of masking steps, which is particularly advantageous for manufacturing. With the folded cell architecture and the self-aligned method, the size of each cell is the minimum pitch, defined as the sum of width and space, in each direction. Therefore, the memory cell 00a can occupy an area of 4F², where “F” is the minimum feature size of a process technology. For example, cell areas of approximately 0.0676 μm and 0.04 μm can be achieved by the present invention using 0.13 μm and 0.10 μm technology generations, respectively.

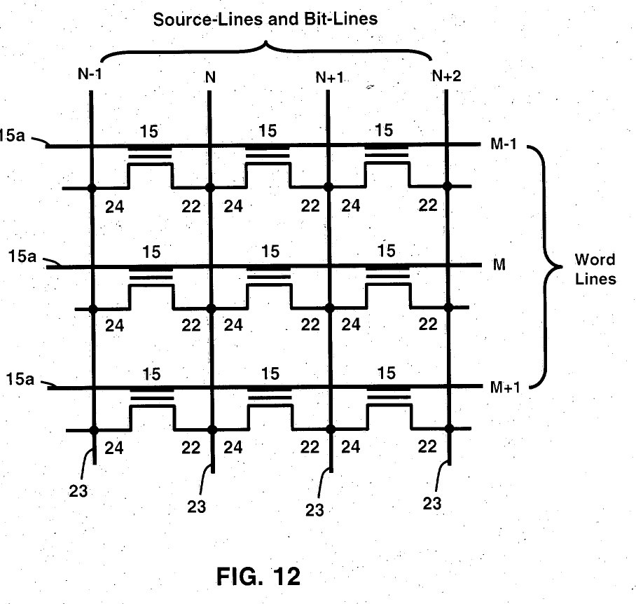

The memory cells of this embodiment is demonstrated in memory array arranged in NOR configuration. Referring to FIG. 12, wherein a NOR array architecture in schematic diagram is shown, and wherein each of the first and second regions 24/22 correspond to the source and drain regions, respectively, of one of the memory cells. The control gate 15 of each of the memory cells 100a in the same row are connected together through one of the word lines 15a. Thereby, the word line M+1 connects the control gates 15 of each of the memory cells in the lowermost row shown in FIG. 12. Each of the bit lines 23 connects all the second regions of memory cells in the same column. Thereby, the bit line N connects the second regions 22 of each of the memory cells in the leftmost column shown in FIG. 12. Since the array demonstrated in this example used the virtual ground array-architecture, the bit line N for memory cells on the leftmost column also functioned as the source line N for memory cells of an adjacent column (i.e. the center column in FIG. 12). Those of skill in the art will recognize that the term source and drain may be interchanged, and the source and drain lines or source and bit lines may be interchanged. Further, the word line is connected to the control gate of the floating gate memory cell. Thus, the term control gate, control gate block or control gate line may also be used interchangeably with the term word line.

The NOR array shown in FIG. 12 is a well-known array architecture used as an example to illustrate the array formation using memory cells of the present invention. Each of the bit lines is arranged to share with cells on an adjacent column as a source line. It should be appreciated that while only a small segment of array region is shown, the provisions in FIG. 12 illustrate any size of array of such regions. Additionally, it should be appreciated by those of ordinary skill in the arts that the memory cells of the present invention can be applied to other type of NOR array architectures. For example, a memory array wherein cells on each column have their own dedicated bit line (i.e. bit line of one cell is not shared with cell on an adjacent column). Furthermore, it should be appreciated by those of ordinary skill in the arts that the memory cells may be arranged in memory array in either NOR or NAND configuration or a combination thereof.

Memory Cell Operation

The operation of the memory cells will now be described below with reference to FIG. 12. For PROGRAM operation, one of the bit cells in the memory array is first located by selecting one of the word lines (WL), and a pair of adjacent source-line/Bit-line (or drain-line). With a bit cell thus selected, the PROGRAM operation can be performed by injecting electrons onto the floating-gate 20 of one of the selected cells 100a using the CHEI (Channel-Hot-Electron Injection) mechanism well-known in the art. This can be done by, for example, applying a voltage (e.g. 3.3V) to the WL to couple enough voltage into the floating gate 20 to turn on the channel 21 of the selected cell while the source is at ground and the drain voltage is at a high voltage (e.g. about 4V). Ground potential is applied to the drain regions 22 for memory cell columns not containing the selected memory cell. Current at source regions 24 are kept below at a minimum level (e.g. about 10⁻¹² amperes or lower) for memory cell columns not containing the selected memory Cell. This can be done by, for example, leaving the source lines of those columns open. Ground potential is applied to the control gates 15 for memory cell rows not containing the selected memory cell. Thus, only the memory cell in the selected row and column is programmed.

For ERASE operation, electron-charges are pulled out from the floating gate via Fowler-Nordheim mechanism. The WL voltage can be at a negative voltage (e.g. −3.3V), whereas source is at a high voltage (e.g. 6V) and drain can be left floating or at ground. Alternately, the WL voltage can be for example at ground while source electrode is at a high voltage (e.g. 9V). The ERASE operation can be done in a small group of such cells (e.g. cells storing a digital word, which contains 8 cells) for byte erase. Additionally, the ERASE can be done in large group of cells (e.g. cells storing code for software program, which can contains 2048 cells configured in page, or contains a plurality of pages in block in array architecture).

Finally, to read a selected memory cell, ground potential is applied to its source region 24. A read voltage of approximately +1 volt is applied to its drain region 22 and approximately 2.5 volts (depending upon the power supply voltage of the device) is applied to its control gate 15. Other regions (i.e. source regions 24) are at ground potential. If the floating gate 20 is positively charged (i.e. the floating gate is discharged of electrons), then the channel region 21 is turned on. Thus, an electrical current will flow from the source region 24 to the drain region 22. This would be the “1” state.

On the other hand, if the floating gate 20 is negatively charged, the channel region 21 is either weakly turned on or is entirely shut off. Even when the control gate 15 and the drain region 22 are raised to the read potential, little or no current will flow through channel region 21. In this case, either the current is very small compared to that of the “1” state or there is no current at all. In this manner, the memory cell is sensed to be programmed at the “0” state. Ground potential can be applied to the source regions 24, drain regions 22, and control gates 15 for non-selected columns and rows so only the selected memory cell is read.

The memory cell can be formed in an array with peripheral circuitry including conventional row address decoding circuitry, column address decoding circuitry, sense amplifier circuitry, output buffer circuitry and input buffer circuitry, which are well known in the art.

Second Embodiment

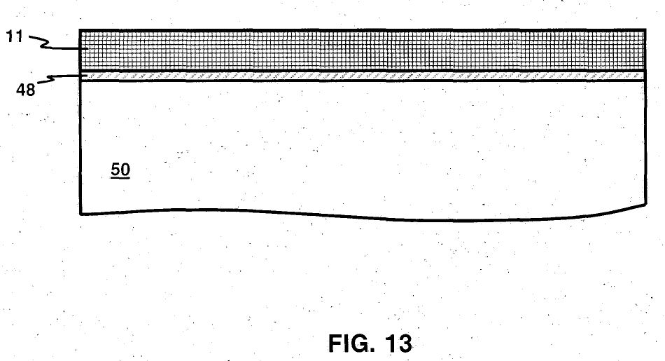

Referring to FIG. 13 there is shown a cross-sectional view of the structure taken along the line CC′ in FIG. 2A with an oxide 48 disposed over a substrate of semiconductor material 50 of the first conductivity type (preferably of p-type silicon). The oxide layer 48 can be formed by using conventional thermal oxidation technique well-known in the art, and can be with a thickness on the order of about 80 Å to about 300 Å. An insulator 11 is formed on top of the oxide layer 48 with thickness preferably at about 800 to about 1500 Å. The insulator 11 can be, e.g., nitride deposited by employing conventional Low Pressure CVD or LPCVD deposition process. The insulator 11 can be in single layer form or in composite layers form with other type of insulator (e.g. combination of oxide and nitride). For process simplicity, a single layer of nitride is employed for the insulator 11. Though not illustrated in FIG. 13, an optional well region of the first conductivity type can be formed in the substrate 50 by ion implantation technique, which introduces impurity thereunto. The depth of the well region can be in the range of about 0.5 μm to about 3 μm into the surface of substrate 50.

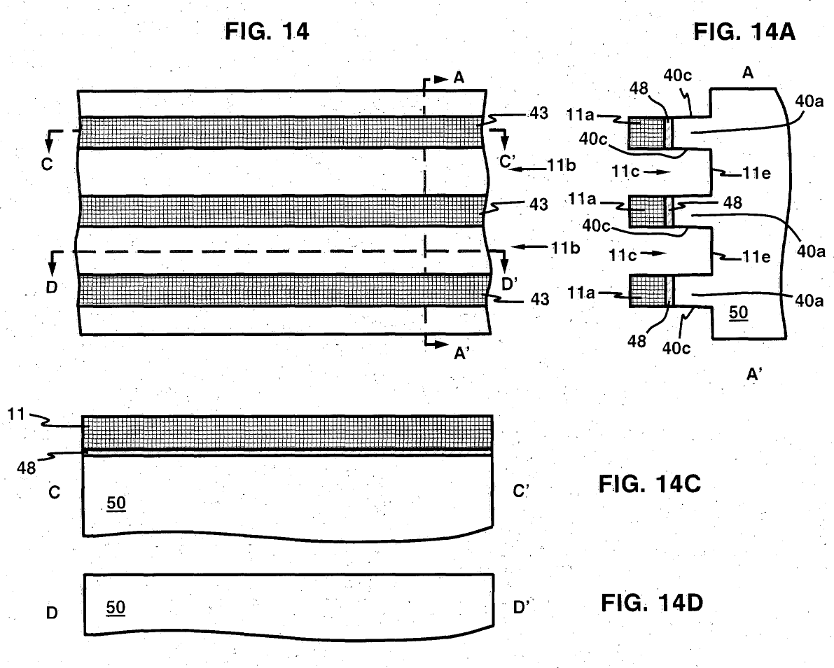

With the structure shown in FIG. 13, the structure is further processed as follows. A photo-resist on the nitride layer 11 is suitably applied followed by a masking step using conventional photo-lithography technique to selectively remove the photo-resist leaving a plurality of photo-resist line traces oriented in a first direction (or “row” direction) over the nitride layer 11. The process is continued by etching the exposed nitride layer 11 followed by an oxide etch to remove the exposed oxide 48 until the silicon substrate is observed, which acts as an etch stop. Next, a controlled silicon etch is performed to etch into the exposed silicon substrate 50 to a predetermined depth (e.g. about 800 Å to about 9000 Å). This step forms a plurality of initial trenches 11c in the substrate 50 (shown in FIG. 14A). The portions of layers 11, 48 and the portion of silicon substrate 50 still underneath the remaining photo-resist are unaffected by this etch process. This step also forms a plurality of traces 43 with each of them comprising a nitride block 11a, an oxide region 48, and a silicon block 40a, which is an elevated silicon mesa on the substrate 50. Due to the nature of RIE etching process, each of the silicon block stripes 40a thus formed can have a cross section being generally rectangular shaped or trapezoidal shaped. Each of the silicon block stripes 40a is spaced apart from an adjacent one by one of the initial trenches 11c, and is self-aligned to one of the oxide regions 48 and a nitride block 11a disposed thereon. The traces 43 are orientated in the first direction with each pair of them spaced apart by a trench stripe 11b (shown in FIG. 14). The width of the traces 43 and the spacing between adjacent traces 43 can be as small as the smallest lithographic feature of the process used. Using the remaining photo-resist as an implant mask, an optional ion implant can be performed to dope the exposed silicon region in the bottom 11e of each of the trenches 11c. The implant impurity can be of a first conductivity type to form channel stopper in each of the trench stripes 11b. The regions where channel stopper are formed are thus self-aligned to the silicon blocks 40a. In areas outside of trenches 11c, the ions are blocked and have no effect. The remaining photo-resist is then removed using conventional means. It should be noted that the ion implantation process could be performed after the removal of photo-resist by using nitride blocks 11a as the implant mask to achieve the same effect. Moreover, it should be readily appreciated by those of ordinary skill in the art that the silicon line blocks 40a need not be a continuous line along the row direction but can be divided into spaced apart segments of blocks through proper defining the photo-resist patterns.

The top plan view of the resulting structure is illustrated in FIG. 14 wherein the traces 43 are shown interlaced with the trench stripes 11b. FIG. 14A illustrates the cross-sectional view along line AA′ to illustrate the formation of the silicon line blocks 40a and the trenches 11c. FIGS. 14C and 14D are cross-sectional view for structure along lines CC′ and DD′ in FIG. 14 and are used to collectively illustrate the structure at this process step along these two lines.

The structure is further processed by forming a plurality of nitride spacers 12 in the trenches 11c. To form nitride spacers 12, a layer of nitride is deposited over the structure, followed by an anisotropic nitride etch, which removes the deposited nitride except for spacers 12 inside the trenches 11c. Each of the nitride spacers 12 is formed laterally adjacent to and covers the sidewalls of regions 11a, 48, and 40a, and can have a width about 200 to about 1000 Å pending on the opening width of the trenches 11c and the generation of the technology employed. The nitride etch step uses the silicon at the bottom 11e of the trenches 11c as the etch stop. Therefore at the end of the etch, a pair of spaced apart nitride spacer line traces 12a is formed within each of the trenches 11c with a gap formed therebetween, wherein a portion of the silicon substrate 50 is exposed at the bottom of trenches 11c.

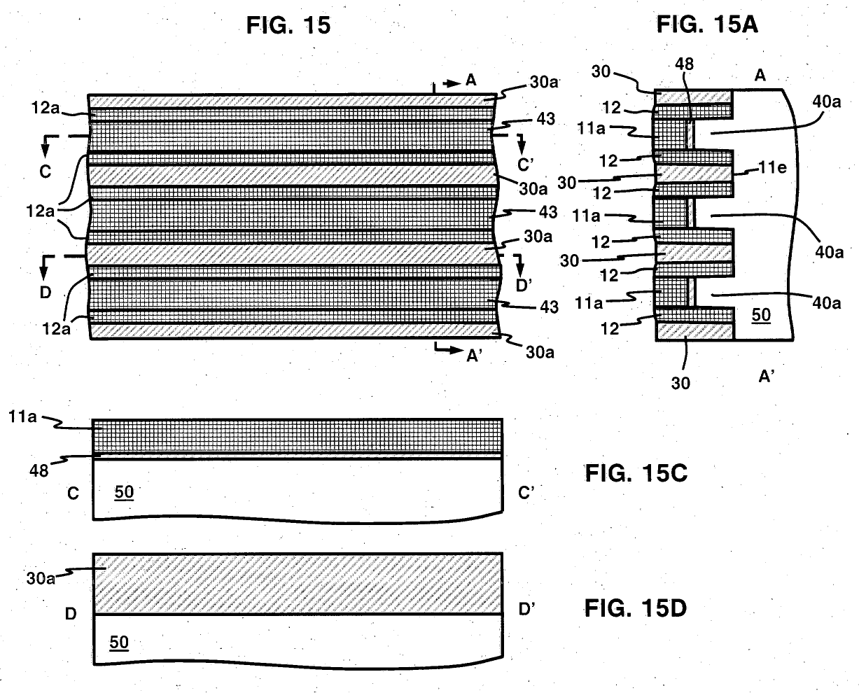

The process is continued by forming a relative thick oxide layer (not illustrated) to fill the gaps in between each pair of nitride spacers 12 using well-known techniques such as conventional LPCVD. The oxide is then selectively removed to leave oxide blocks 30 in region between the nitride spacer line traces 12a (FIG. 15A). The preferable structure is with the top surface of the oxide blocks 30 substantially co-planar with the top surface of nitride blocks 11a. This can be done by, for example, employing a chemical-mechanical polishing (CMP) process to planarize the thick oxide followed by an RIE (reactive ion etch) using nitride blocks 11a as an etching stopper. An optional oxide over-etching step follows if necessary to clear any oxide residue on the nitride blocks 11a. Thereby, the process leaves oxide only in region between the nitride spacer line traces 12a to form oxide blocks 30 self-aligned thereto. The process forms a plurality of oxide line traces 30a oriented in the first direction and interlaced with a plurality of nitride stripes, wherein each of the nitride stripes comprises a nitride block 11a and a pair of nitride spacers 12. The top plan view of the resulting structure is illustrated in FIG. 15. The cross-sectional views of the resulting structure are collectively illustrated in FIGS. 15A, 15C, and 15D.

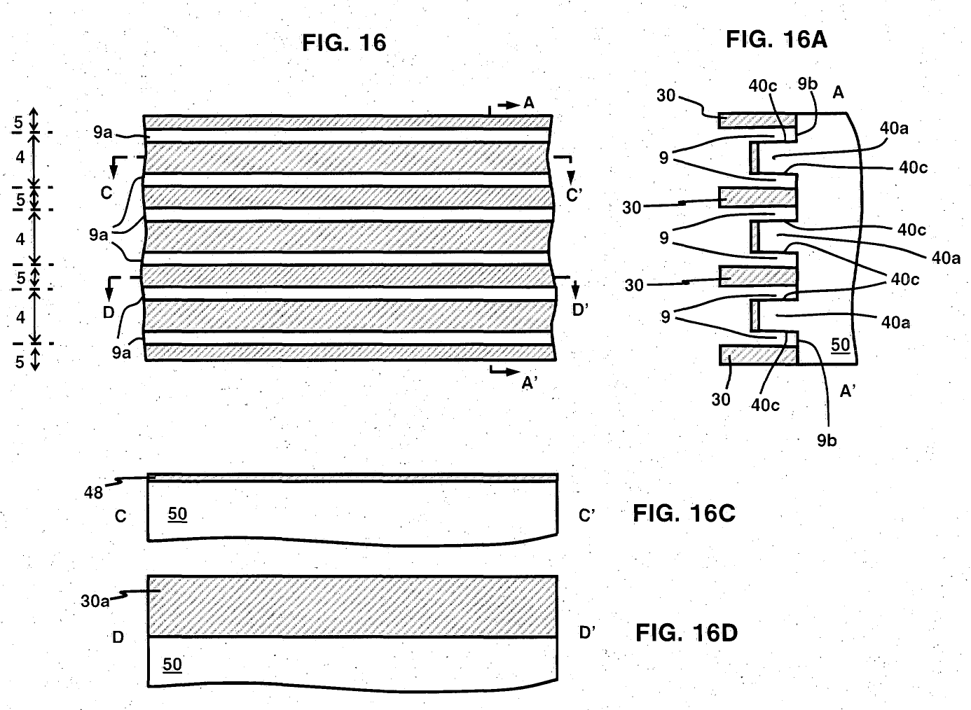

The process is then followed by an etching step removing the nitride spacers 12 and the nitride blocks 11a (e.g. using hot phosphoric acid) to form a plurality of trench traces 9a oriented in the first direction. This etching step forms a plurality of first trenches 9 with each of the first trenches 9 formed in between one of the oxide blocks 30 and one of the silicon blocks 40a. After the nitride etch, the sidewalls 40c of the silicon blocks 40a and the bottom 9b of the first trenches 9 are exposed (FIG. 16A). The bottom 9b of the first trenches 9 also expose portions of the substrate 50 to the air. The oxide blocks 30 correspond to the isolation regions 5 of the memory cells. Each adjacent pair of the oxide blocks 30 defines an active region 4 therebetween. The top plan view of the resulting structure is illustrated in FIG. 16 with the active regions 4 interlaced with the isolation regions 5. The cross-sectional views of the resulting structure are collectively illustrated in FIGS. 16A, 16C, and 16D.

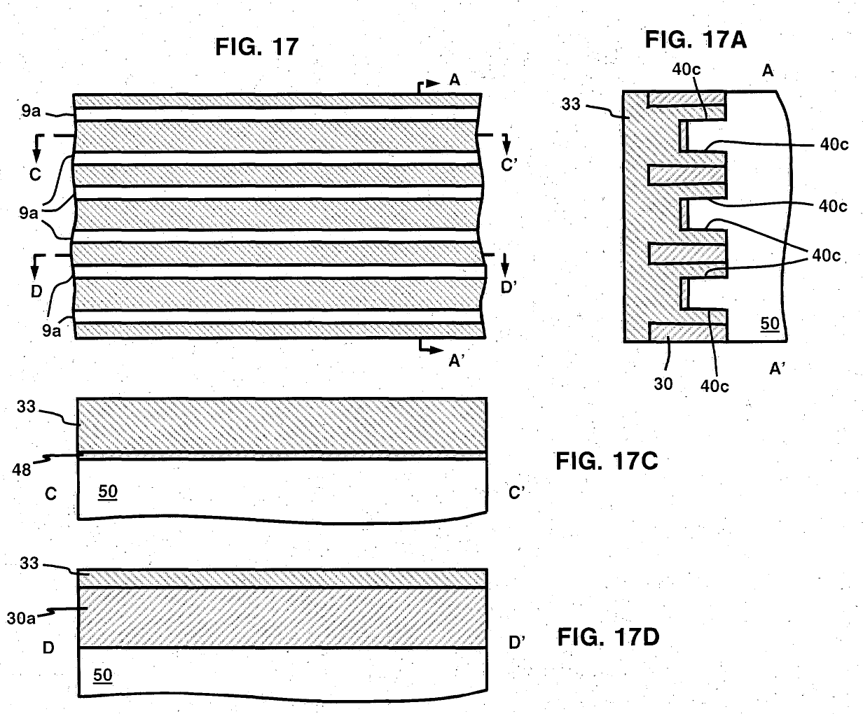

A first layer of electrically conductive material 33 such as polysilicon is deposited over the structure using, for example, conventional LPCVD technique with polysilicon film doped in-situ or by subsequent ion implantation. The polysilicon layer thus formed is heavily doped with-impurity of a second conductivity type at a doping level in the range of about 1×10¹⁸ atoms/cm³ to about 5×10²¹ atoms/cm³. The polysilicon layer 33 is with a thickness thick enough to fill the trenches 9 and can be on the order of, for example, about 700 Å to 3000 Å. Preferably, the topography of the polysilicon layer 33 thus formed is substantially planar, and an optional planarization process (i.e. CMP) can be used for achieving the planar topography. The polysilicon region 33 fills each of the first trenches 9 and is in direct physical contact with the sidewalls 40c of each of the silicon blocks 40a, as shown in FIG. 17A. Similar to the consideration in the first embodiment, though polysilicon is chosen here for the conductive layer 33, in general, any other materials that can be used as an impurity diffusion source, having a low to sheet resistance, a good gap filling capability, and stable material property at high temperature (e.g. 1000° C.) can be employed instead. For example, a metalized polysilicon layer such as polysilicon with tungsten-polycide atop can be employed for the conductive layer 33 by using well-known CVD technique. The top plan view of the resulting structure is shown in FIG. 17 and the cross-sectional views of the resulting structure are collectively illustrated in FIGS. 17A, 17C, and 17D.

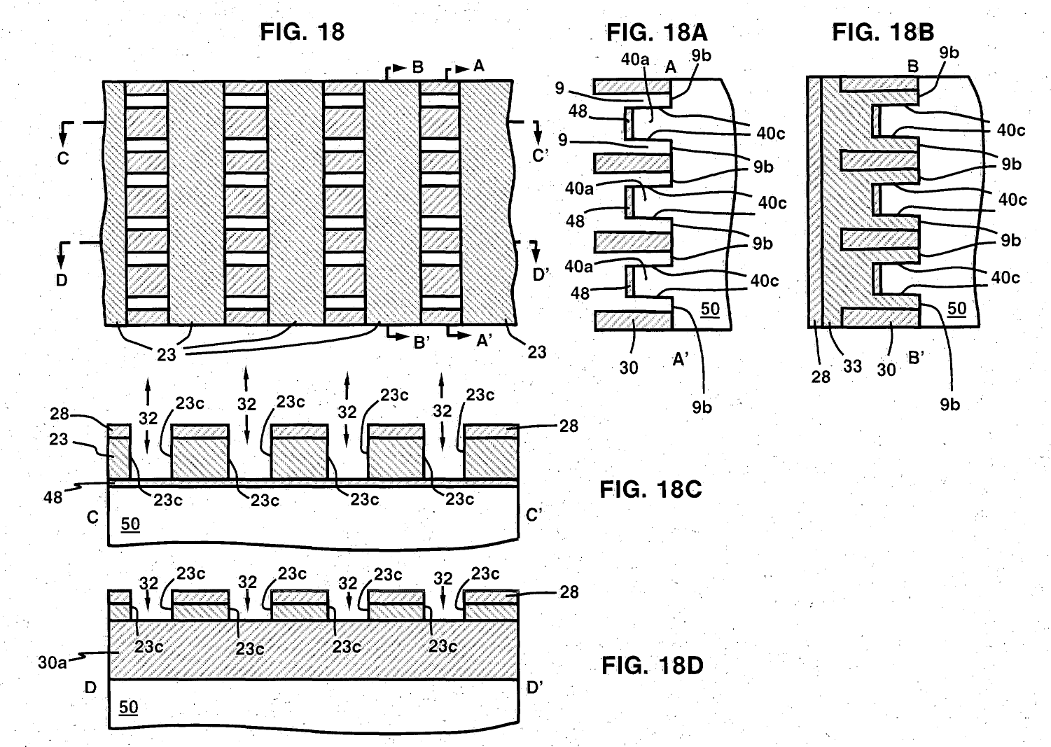

A thick insulating layer 28 with thickness on the order of about 500 Å to 1000 Å is formed over the polysilicon layer 33. The insulating layer 28 can be in a single layer film made of oxide or nitride, or can be in a composite layers form comprising a combination of oxide and nitride films. For illustration purpose, here oxide is chosen as example for the insulating layer 28. Next, a photo-resist is formed over the oxide layer 28 followed by a masking step using conventional photo-lithography technique to selectively remove the photo-resist leaving a plurality of photo-resist stripes over the oxide layer 28 and oriented in a second direction substantially perpendicular to the first direction (for defining the Source Lines/Bit Lines or Source Lines/Drain Lines). The process is continued by using an anisotropic etch process, such as RIE, to remove the exposed oxide layer 28 followed by a polysilicon etch to remove the exposed polysilicon layer 33 thereunder. Due to the heavy doping concentration in the polysilicon 33, the polysilicon etch is with a high selectivity to the silicon substrate 50. The etch process continues until the silicon substrate 50 is observed, which acts as an etch stop. This etch forms spaced apart Source Lines/Bit Lines (SL/BLs) 23, which are generally parallel to one another and extend in the second direction, with a trench stripe 32 between each pair of adjacent SL/BLs. The portions of layers 28 and 33 still underneath the remaining photo-resist are unaffected by this etch process. The portions of silicon blocks 40a in the trench stripe regions 32 are uncovered by the photo-resist but are protected by the oxide regions 48, and hence are not affected by this etch process as well (FIG. 18A). The space between adjacent SL/BLs 23 and the width of each SL/BLs 23 can be as small as the smallest lithographic feature of the process used. This step also reforms the first trenches 9 in the trench stripes regions 32 and re-exposes portions of the substrate 50 in that regions to the air. The remaining photo-resist is then removed using conventional means. The top plan view of the resulting structure is illustrated in FIG. 18 with SL/BLs 23 interlaced with the trench stripes 32. FIG. 18A illustrates the cross-sectional view along line AA′ to illustrate the complete removal of the polysilicon layer 33 in first trenches 9 in one of the trench stripe regions 32. Both the sidewalls 40c of the silicon blocks 40a and the bottoms 9b of the first trenches 9 in the trench stripe regions 32 are exposed to the air at this process step. FIG. 18B illustrates the cross-sectional view along line BB′, which corresponds to the SL/BL regions 23 in FIG. 18. The sidewalls 40c of the silicon blocks 40a and the bottoms 9b of the first trenches 9 are electrically contacted to the polysilicon 33 of each of the SL/BLs 23. FIGS. 18C and 18D are cross-sectional view for structure along lines CC′ and DD′ in FIG. 18 and are used to collectively illustrate the structure at this process step along these two lines. The sidewalls 23c of each of the SL/BLs 23 are shown exposed to the air in both FIGS. 18C and 18D.

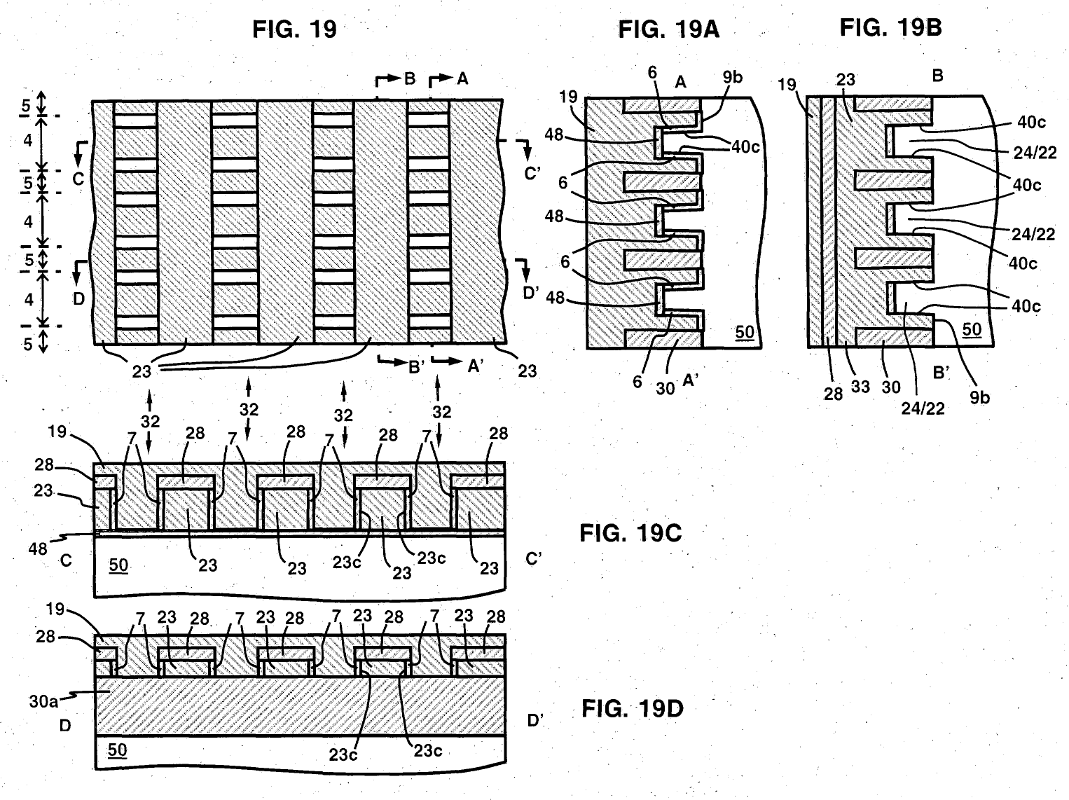

The process is continued by forming insulator such as oxide on the exposed portion of silicon and polysilicon regions as described in FIGS. 18A-18D. This can be done by, for example, using conventional thermal oxidation technique to form oxide film with thickness on the order of about 50 Å to about 200 Å, and is preferably about 80 Å. The oxidation step forms oxide regions 6 on both the sidewalls 40c of the silicon blocks 40a and the bottoms 9b of the first trenches 9 in the trench stripes regions 32 (FIG. 19A). Within an active region 4 in each of the trench stripe regions 32, there is a pair of oxide regions 6 joining with the oxide regions 48 therein to form the first insulating layer 44 (defined in FIG. 1B). The step thus forms a plurality of insulating layer regions 44, with each of the insulating layer regions 44 disposed laterally adjacent to and over one of the silicon blocks 40a in the trench stripe regions 32. The insulating layer regions 44 further cover the exposed substrate regions 50 in the trench stripe regions 32. The same, oxidation also forms oxide regions 7 on the sidewalls 23c of the SL/BLs 23. Each of the oxide regions 7 joins with one of the oxide regions 28 in forming an insulating layer that is disposed laterally adjacent to and over one of the SL/BLs 23 (FIGS. 19C-19D). During this thermal process, impurity in the polysilicon 33 of each of the SL/BLs 23 out-diffuse into the silicon blocks 40a in portions having the sidewalls 40c contacted by the SL/BLs 23. The portion of silicon blocks where impurity diffuses into forms the first and the second regions 24/22 of the memory cells. The SL/BLs 23 thus formed extend continuously across the isolation and active regions 5/4, and thus electrically connect all the first regions 24 together and all the second regions 22 together for each column of memory cells extending in the second direction.

Thereafter, a second polysilicon layer 19 is formed over the structure by, for example, using conventional LPCVD technique with polysilicon film doped either in-situ or through a subsequent ion implantation. The second polysilicon layer 19 can be with thickness from about 500 Å to about 1000 Å and is to be used to form the floating-gate region 20 of the memory cell. The second polysilicon layer 19 thus formed is disposed over the trench stripe regions 32 and over the SL/BL regions 23. For the polysilicon layer 19 over the trench stripe regions 32, the polysilicon 19 fills each of the trenches stripes and is disposed over and laterally adjacent to each of the silicon blocks 40a with oxide regions 6 and 48 insulating the polysilicon 19 from each of the silicon blocks 40a, as shown in FIG. 19A. For the polysilicon layer 19 over the SL/BL regions 23, the polysilicon layer 19 is formed over and insulated from each of the SL/BLs 23 by the oxide layer 28, as shown in cross-sectional view in FIG. 119B. The second polysilicon layer 19 in each of the trench stripes 32 is formed laterally adjacent to and insulated from the SL/BLs 23 by the oxide regions 7, as shown in the cross-sectional view in FIGS. 19C and 19D. The topography of the second polysilicon layer 19 thus formed is substantially planar. The top plan view of the resulting structure is shown in FIG. 19 and the cross-sectional views of the resulting structure are collectively illustrated in FIGS. 19A, 19B, 19C, and 19D.

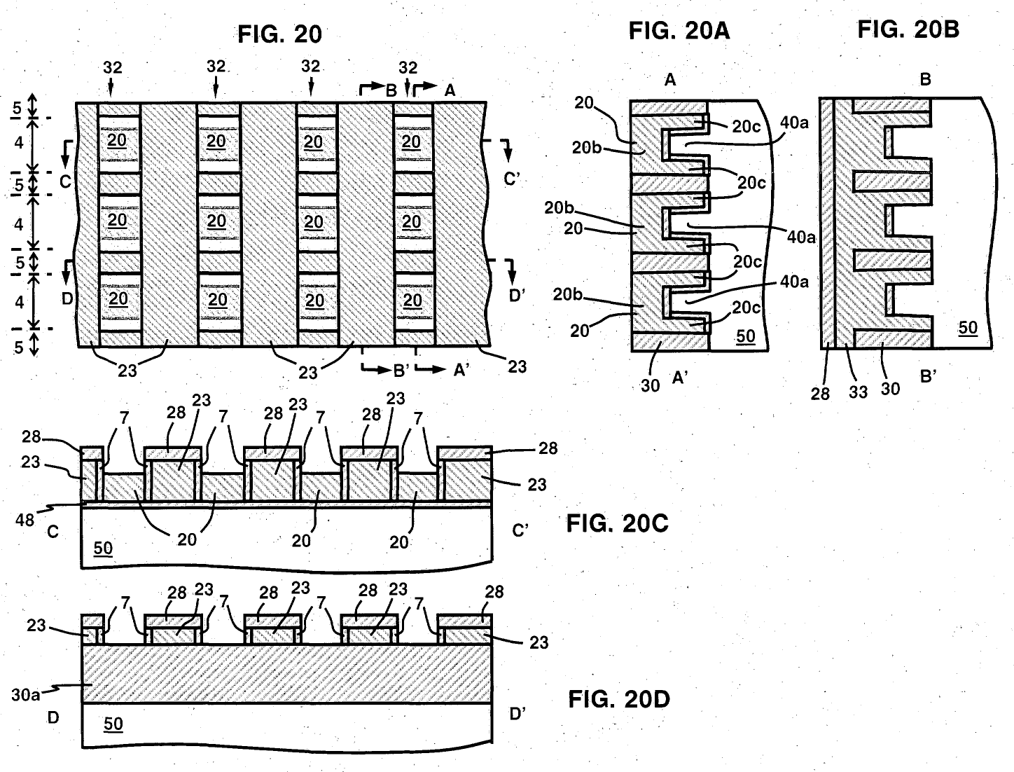

A polysilicon etch follows thereafter to remove the second polysilicon layer 19 on the oxide blocks 30 in the trench stripe regions 32. The portion of polysilicon 19 on the oxide insulator 28 is also removed in the same etch leaving remaining polysilicon 19 in between adjacent oxide blocks 30 and within trenches 9 in the trench stripe regions 32 (FIG. 20A). This can be done by, for example, using conventional anisotropic etch technique such as RIE. A proper over-etch can be optionally:applied to the structure to ensure the second polysilicon 19 is completely removed frown the top surfaces of oxide blocks 30 in trench stripe regions 32 and of oxide layer 28 in SL/BL regions 23. This forms the floating-gates 20 with folded architecture each self-aligned to one of the active regions and to a pair of adjacent SL/BL regions. The exposed surface of the remaining polysilicon 19 is substantially co-planar with or slightly below the top surface of oxide blocks 30, as shown in FIG. 20A. The top plan view of the resulting structure is shown in FIG. 20. An array of floating gates 20 is shown in FIG. 20, wherein each of the floating gates 20 thus formed comprises a pairs of vertical sections 20c (first and second sections), each laterally adjacent to one of the sidewalls of one of the silicon block 40a, and a horizontal section 20b (third section) over the top of the one silicon blocks 40a. The cross-sectional views of the resulting structure are collectively illustrated in FIGS. 20A, 20B, 20C, and 20D.

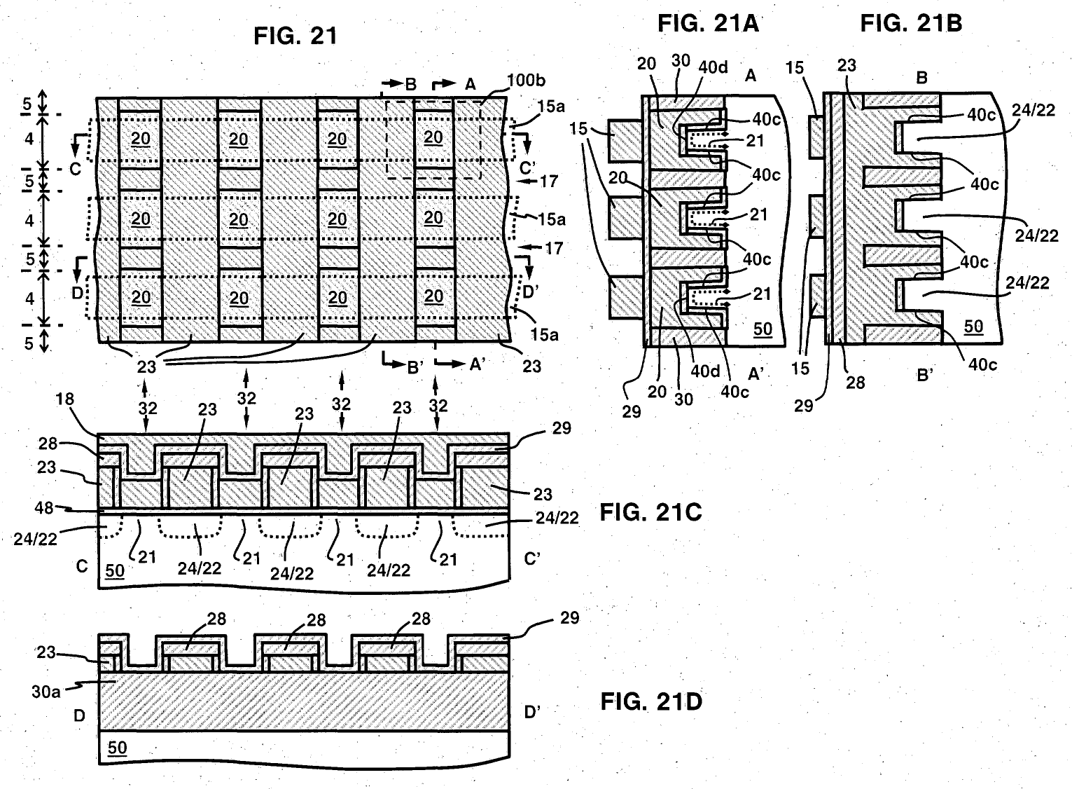

The structure is further processed by forming a second insulating layer 29 such as oxide with thickness on the order of about 50 Å to 300 Å using conventional deposition technique or thermal oxidation process. The insulator 29 can also be formed in composite layers comprising more than two different dielectrics (e.g. oxide-nitride-oxide tri-layers). For process simplicity, an oxide layer of HTO (high temperature oxide) is chosen here as the second insulating layer 29 for illustration purpose. Next, an electrically conductive layer, 18 with thickness on the order of about 500 to 4000 Å is deposited over the structure. The layer 18 can be made of, for example, polysilicon, W-polycide or metals, and is to be used to form the control gate block 15 for each of the memory cells 100b. For an illustration, polysilicon is chosen here for the layer 18 with the topography preferably planar. An optional metalized polysilicon (not shown) can be deposited on the polysilicon to reduce its sheet resistance using well-known Chemical-Vapor-Deposition (CVD) technique. Thereafter, a photo-resist is formed over the polysilicon layer 18 followed by a masking step using conventional photo-lithography technique to selectively remove the photoresist leaving a plurality of photo-resist stripes over the polysilicon layer 18 and oriented in the first direction. Each of the photo-resist stripes is properly aligned to one of the active regions 4. The process is continued by using an anisotropic etch process, such as RIE, to remove the exposed polysilicon layer, 18 until the oxide layer 29 is observed, which acts as an etch stop. The portions of polysilicon layer IS still underneath the remaining photo-resist are unaffected by this etch process. This etching step forms a plurality of control gates 15 each disposed over and insulated from one of the floating gates 20. The etch also forms a plurality of spaced apart word lines 15a,which are generally parallel to one another and extend in the first direction with a trench stripe 17 between each pair of adjacent word lines 15a (FIG. 21). Each of the word lines 15a extends continuously across the SL/BLs 23 and the trench stripe regions 32 to connect together a row of the control gates 15 in that row of memory cells. The space between adjacent word lines 15a and the width of each of the word lines 15a can be as small as the smallest lithographic feature of the process used. The remaining photo-resist is then removed using conventional means. The top plan view of the resulting structure is shown in FIG. 21, wherein the border of one of the memory cells 100b is shown. The memory cells 100b are arranged along with the floating gates 20 in an array of rows extending in the first direction and columns in the second direction. In each of the silicon line blocks 40a of the resulting structure, the portions of 40a under the SL/BLs 23 correspond to the first and second regions 24/22 of the memory cells 10b, as shown in FIG. 21C. Each of thee first and second regions 24/22 is electrically contacted to the SL/BLs 23 through the sidewalls 40c of each of the silicon blocks 40a, as shown in FIG. 21B. Each of the channel region 21 is defined in between a pair of the first and second regions 24/22, as shown in FIG. 21C, and are formed under and adjacent to the surfaces of the top 40d and sidewalls 40c of the silicon blocks 40a, as shown in FIG. 21A. The cross-sectional views of the resulting structure are collectively illustrated in FIGS. 21A, 21B, 21C, and 21D. The memory cell is a three-dimensional structure. During cell operations, the channel carriers flow from the first region 24 to the second region 22 along the channel in a direction orthogonal to that of FIG. 21A.

The structure can be further processed by following conventional backend process steps as described in the first embodiment to form a passivation and bonding pads atop the structure.

The operation method on cell 100b is the same as that in the first embodiment. The memory cell array formed thereby has the same advantages as outlined in the first embodiment.

Third Embodiment

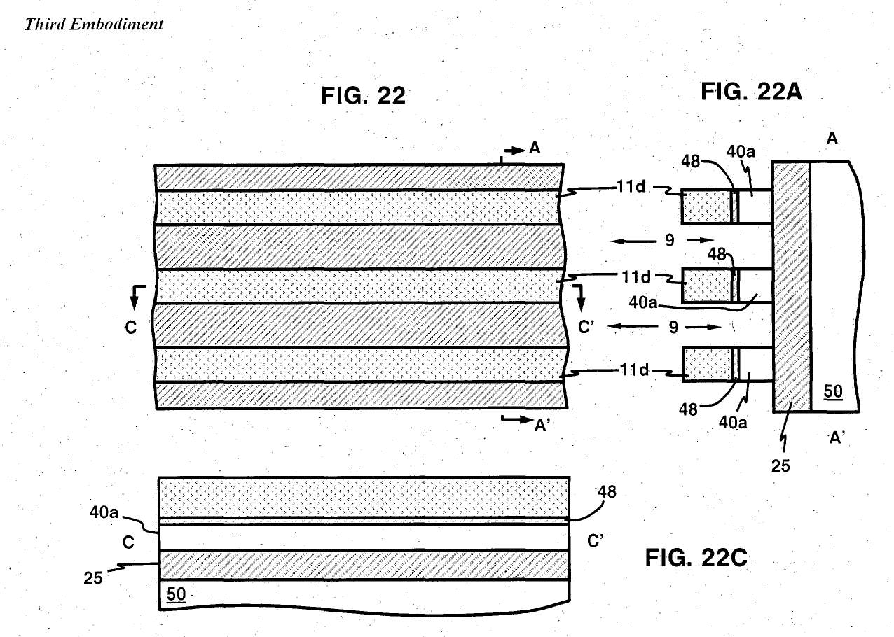

FIGS. 22 to 28 and figures of associated cross-sectional view illustrate manufacturing method for the third embodiment, wherein a process scheme is used to form floating gate with control gate self-aligned thereto for memory cell of folded floating gate structure. The manufacturing method for this alternate embodiment begins with the same structure as shown in FIG. 2B.

An insulating layer 48, such as oxide; is formed by using conventional thermal oxidation technique well-known in the art, and can be with a thickness on the order of about 80 Å to about 300 Å. While not shown in FIG. 2B, an optional well region of the first conductivity type can be formed in the semiconductor layer 40 by ion implantation technique, which introduces impurity into the layer 40.

The structure is further processed as follows. A photo-resist on the oxide layer 48 is suitably applied followed by a masking step using conventional photo-lithography technique to selectively remove the photo-resist leaving a plurality of photo-resist line traces 11d oriented in a first direction over the oxide layer 48. The process is continued by using an anisotropic etching technique (e.g. RIE) to remove the exposed oxide layer 48 and the underlying silicon layer 40 until insulating layer 25 is observed, which acts as an etch stop (FIG. 22A). The portions of layers 48 and 40 underneath the remaining photo-resist traces 11d are unaffected by this etch process. This step forms a plurality of first trenches 9 and a plurality of traces orientated in the first direction, with each of the traces comprises a photo-resist 11d, an oxide region 48 and a silicon block 40a. The silicon line blocks 40a thus formed each is spaced apart from an adjacent one by a first trench 9, and is self-aligned to one of the oxide regions 48 disposed thereon. The width of each of the silicon block stripes 40a and the spacing between adjacent block stripes 40a can be as small as the smallest lithographic feature of the process used. Due to the nature of RIE etching process, each of the silicon block stripes 40a thus formed can have a cross section being generally rectangular shaped or trapezoidal shaped. It should be readily appreciated by those of ordinary skill in the art that the silicon line blocks 40a need not be a continuous line along the row direction but can be divided into spaced apart segments of blocks through proper definition on the photo-resist patterns. The top plan view of the resulting structure is illustrated in FIG. 22, wherein the traces 11d are shown interlaced with the stripes formed by the first trenches 9. FIG. 22A illustrates the cross-sectional view along line AA′ to illustrate the formation of the silicon line blocks 40a and the trenches 9. FIG. 22C is a cross-sectional view for structure along line CC′ in FIG. 22 at this process step.

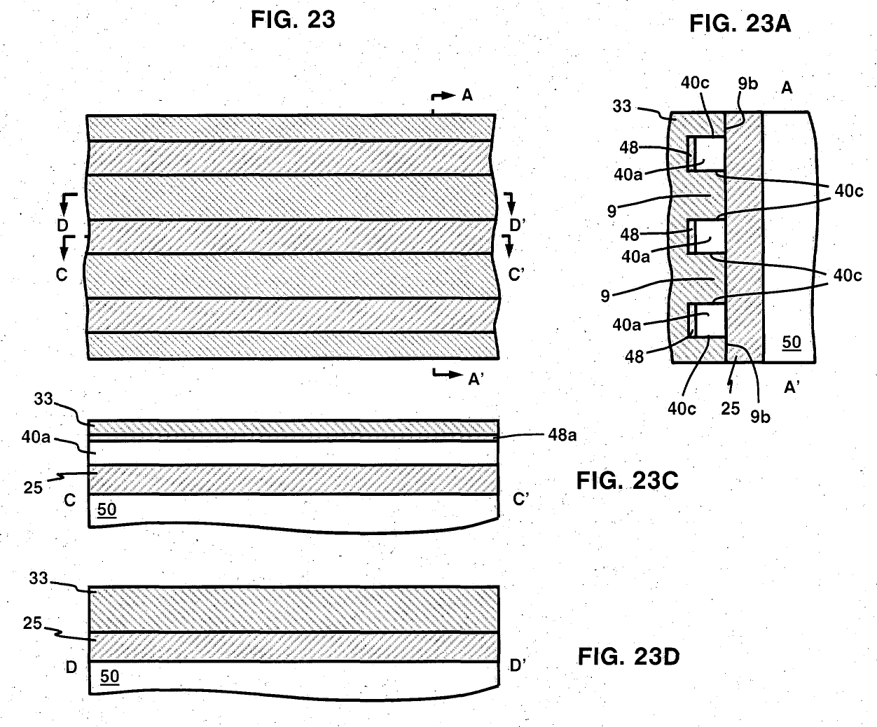

The remaining photoresist is then removed using conventional means. Next, a first layer of electrically conductive material 33 such as polysilicon is deposited over the structure using, for example, conventional LPCVD technique with polysilicon film doped in-situ or by a Subsequent ion implantation. The polysilicon layer thus formed is heavily doped with impurity of a second conductivity type at a doping level in the range of about 1×10¹⁵ atoms/cm to about 5×10²¹ atoms/cm³. The polysilicon layer 33 is with a thickness thick enough to fill the trenches 9 and can be on the order of, for example, about 700 Å to 3000 Å. Preferably, the topography of the polysilicon layer 33 thus formed is substantially planar, and an optional planarization process (i.e. CMP) can be used for achieving the planar topography. The polysilicon region 33 fills each of the trenches 9 and is in direct physical contact with the sidewalls 40c of each of the silicon blocks 40a, as shown in FIG. 23A. Similar to the consideration in the first embodiment, though polysilicon is chosen here for the conductive layer 33, in general, any other materials that can be used as an impurity diffusion source, having a low sheet resistance, a good gap filling capability, and stable material property at high temperature (e.g. 1000° C.) can be employed instead. For example, a metalized polysilicon layer such as polysilicon with tungsten-polycide atop can be employed for the conductive layer 33 by using well-known CVD technique. The top plan view of the resulting structure is shown in FIG. 23 and the cross-sectional views of the resulting structure are collectively illustrated in FIGS. 23A, 23C, and 23D.

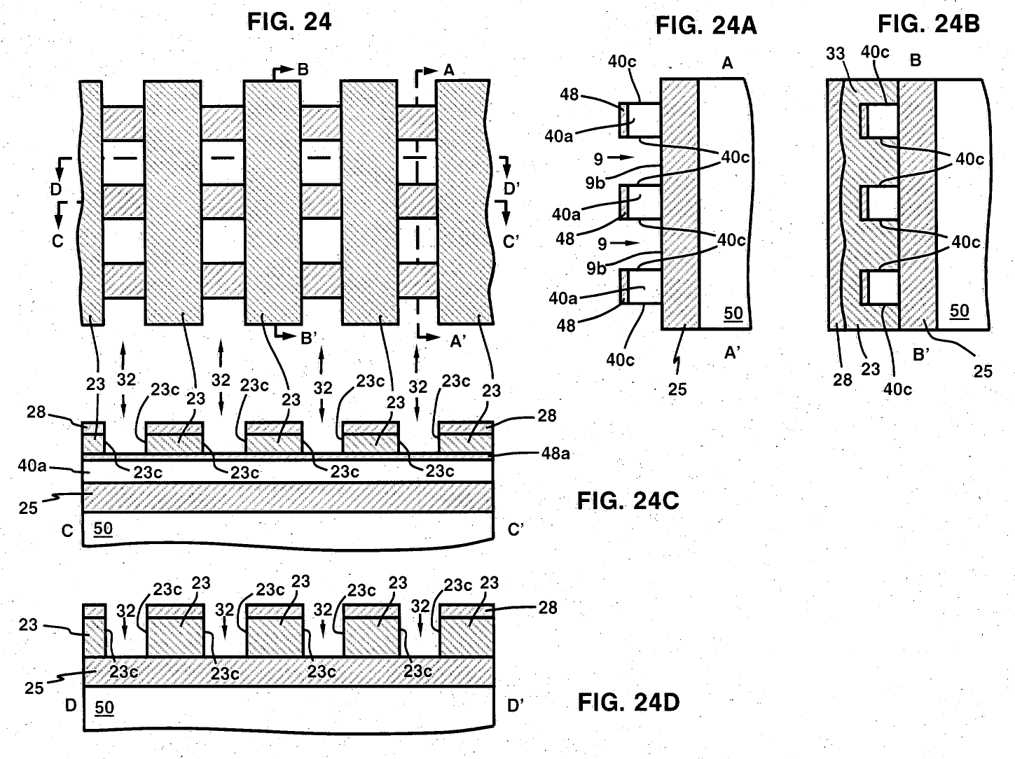

A thick insulating layer 28 with thickness on the order of about 500 Å to 1000 Å is formed over the polysilicon layer 33. The insulating layer 28 can be in a single layer film made of oxide or nitride, or can be in a composite layers form comprising a combination of oxide and nitride films. For illustration purpose, here oxide is chosen as example for the insulating layer 28. Next, a photo-resist is formed over the oxide layer 28 followed by a masking step using conventional photo-lithography technique to selectively remove the photo-resist leaving a plurality of photo-resist stripes over the oxide layer 28 and oriented in a second direction substantially perpendicular to the first direction (for defining the Source Lines/Bit Lines or Source Lines/Drain Lines 23). The process is continued by using an anisotropic etch process, such as RIE, to remove the exposed oxide layer 28 followed by a polysilicon etch to remove the exposed polysilicon layer 33 thereunder. The etch process continues until the insulating layer 25 is observed, which acts as an etch stop. This etch forms spaced apart Source Lines/Bit Lines (SL/BLs) 23, which are generally parallel to one another and extend in the second direction, with a trench stripe 32 between each pair of adjacent SL/BLs 23. The portions of layers 28 and 33 still underneath the remaining photo-resist are unaffected by this etch process (FIG. 24B). The portions of silicon blocks 40a in the trench stripe regions 32 are uncovered by the photo-resist but are protected by the oxide regions 48, and hence are not affected by this etch process as well (FIG. 24A). The space between adjacent SL/BLs 23 and the width of each SL/BL 23 can be as small as the smallest lithographic feature of the process used. This step also re-exposes the trenches 9 in the trench stripes regions 32 to the air. The remaining photo-resist is then removed using conventional means. The top plan view of the resulting structure is illustrated in FIG. 24 with SL/BLs 23 interlaced with the trench stripes 32. FIG. 24A illustrates the cross-sectional view along line AA′ to illustrate the complete removal of polysilicon layer 33 in first trenches 9 in one of the trench stripe regions 32. Both the sidewalls 40c of the silicon blocks 40a and the bottoms 9b of the first trenches 9 in the trench stripe regions 32 are exposed to the air at this process step. FIG. 24B illustrates the cross-sectional view along line BB′, which corresponds to the SL/BL regions 23 in FIG. 24. The polysilicon 33 of each of the SL/BLs 23 is electrically contacted to the sidewalls 40c of the silicon blocks 40a. The SL/BLs 23 thus formed are electrically insulated from the substrate 50 by the insulating layer 25. FIGS. 24C and 24D are cross-sectional view for structure along lines CC′ and DD′ in FIG. 24 and are used to collectively illustrate the structure at this process step along these two lines. The sidewalls 23c of each of the SL/BLs 23 are shown exposed to the air in both FIGS. 24C and 24D.

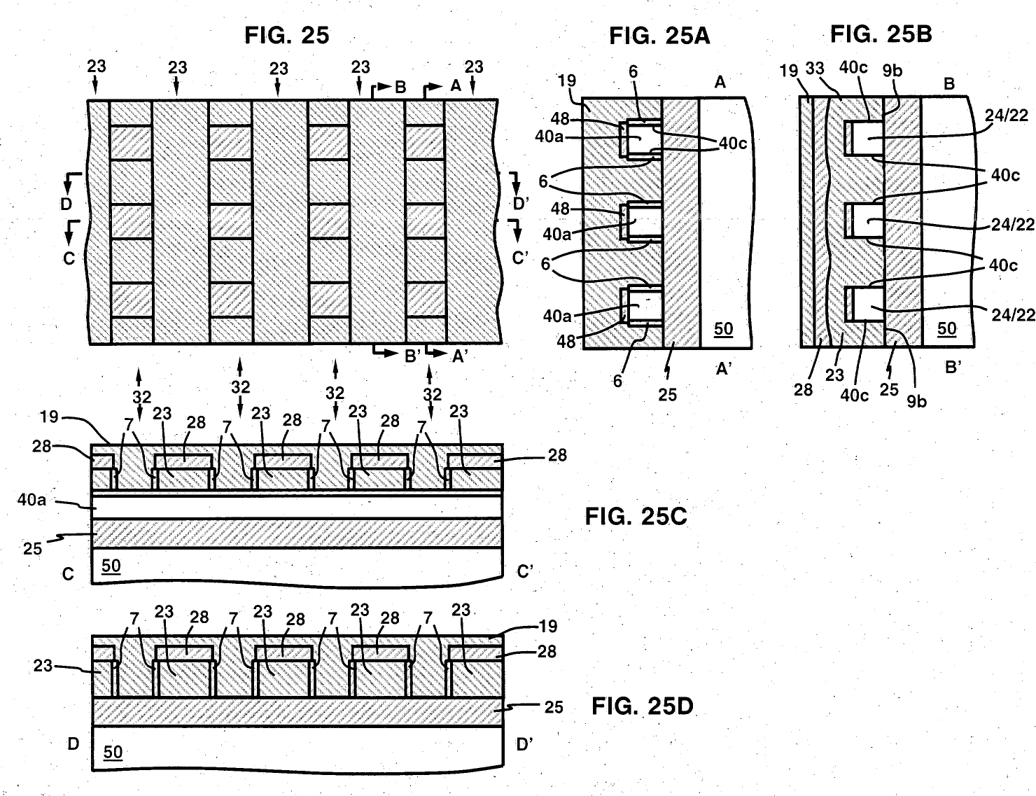

The process is continued by forming insulator such as oxide on the exposed portion of silicon and polysilicon regions as shown in FIGS. 24A-24D. This can be done by, for example, using conventional thermal oxidation technique to form oxide film with thickness on the order of about 50 A to about 200 A, and is preferably about 80 A. The oxidation step forms oxide regions 6 on both the sidewalls 40c of each of the silicon blocks 40a that are exposed in the trench stripes regions 32 (FIG. 25A). Each pair of these oxide regions 6 joins with the oxide region 48 of the same silicon block 40a to form the first insulating layer 44 (defined in FIG. 1C). The step thus forms a plurality of insulator regions 44, with each of the insulating layer regions 44 disposed laterally adjacent to and over one of the silicon blocks 40a in the trench stripe regions 32. The same oxidation also forms oxide regions 7 on the sidewalls 23c of the SL/BLs 23 (FIGS. 25C-25D). Each of the oxide regions 7 joins with one of the oxide regions 28 in forming an insulating layer that is disposed laterally adjacent to and over one of the SL/BLs 23. During this thermal process, impurity in the polysilicon 33 of each of the SL/BLs 23 out-diffuse into the silicon blocks 40a in portions having the sidewalls 40c contacted by the SL/BLs 23. The portion of silicon blocks where impurity diffuses into forms the first and the second regions 24/22 of the memory cells (FIG. 25B). The SL/BLs 23 thus formed extend continuously to electrically connect all the first regions 24 together and all the second regions 22 together for each column of memory cells extending in the second direction.

Thereafter, a second layer of electrically conductive material 19, such as polysilicon layer, is formed over the structure by, for example, using conventional LPCVD technique with polysilicon film doped either in-situ or through a subsequent ion implantation. The second polysilicon layer 19 can be with thickness from about 500 Å to about 1000 Å, and is to be used to form the floating-gate region 20 of the memory cell. The second polysilicon layer 19 thus formed is disposed over the trench stripe regions 32 and over the SL/BL regions 23. For the polysilicon layer 19 over the trench stripe regions 32, the polysilicon 19 fills each of the trenches stripes and is disposed over and laterally adjacent to each of the silicon blocks 40a with oxide regions 6 and 48 insulating the polysilicon 19 from each of the silicon blocks 40a, as shown in FIG. 25A. For the polysilicon layer 19 over the SL/BL regions 23, the polysilicon layer 19 is deposited over and insulated from each of the SL/BLs 23 by the oxide layer 28, as shown in cross-sectional view in FIG. 25B. The second polysilicon layer 19 in each of the trench stripes 32 is formed laterally adjacent to and insulated from the SL/BLs 23 by the oxide regions 7, as shown in the cross-sectional view in FIGS. 25C and 25D. The topography of the second polysilicon layer 19 thus formed is substantially planar. The top plan view of the resulting structure is shown in FIG. 25 and the cross-sectional views of the resulting structure are collectively illustrated in FIGS. 25A, 215B, 25C, and 25D.

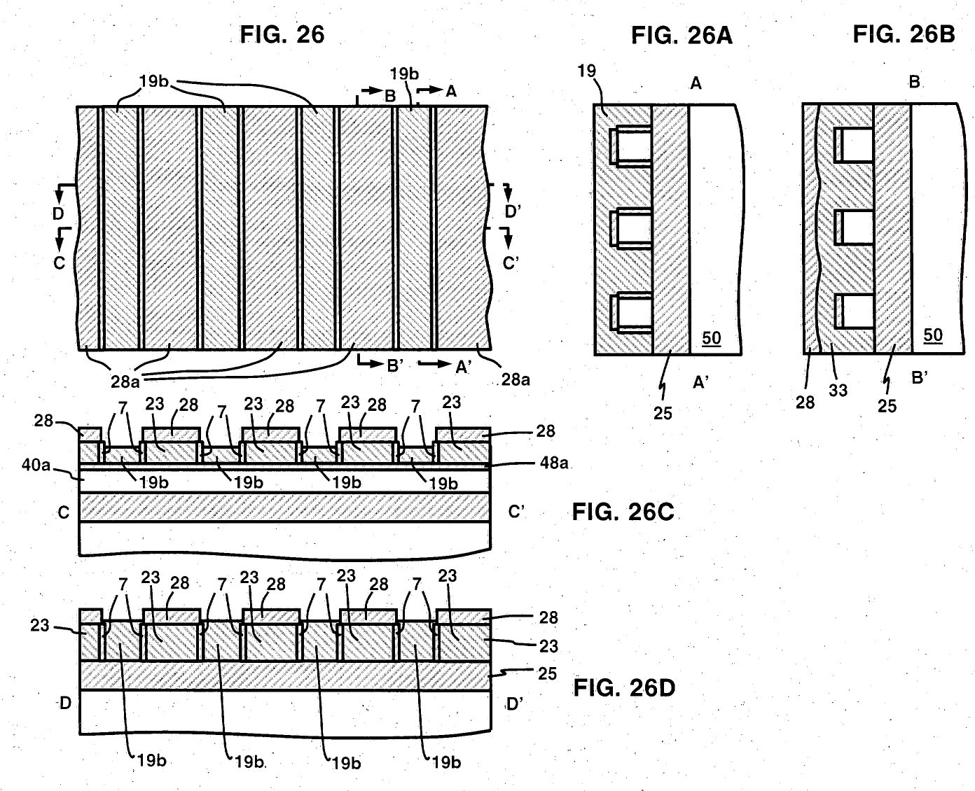

A polysilicon etch follows thereafter to remove the second polysilicon layer 19 on the oxide 28 leaving the polysilicon layer 19 only within the trench stripe regions 32 (FIG. 26A). This can be done by, for example, using conventional anisotropic etch technique such as RIE or CMP process with the oxide regions 28 as etch stop. A proper over-etch can be optionally applied to the structure to ensure the second polysilicon 19 is completely removed from the top surfaces of the oxide regions 28. This step forms a plurality of polysilicon stripes 19b oriented in the second direction with each of the polysilicon stripes be spaced apart and isolated from an adjacent one (FIG. 26). The same etch also exposes the top surface of a plurality of oxide stripes 28a, with each of the oxide stripes 28a disposed over one of the SL/BLs blocks 23. As will be described hereinafter, the polysilicon 19 in polysilicon stripes 19b will be used for floating gate formation. The top plan view of the resulting structure is shown in FIG. 26, wherein the polysilicon stripes 19a are shown interlaced with the oxide stripes 28a, and hence with the SL/BLs regions 23. The cross-sectional views of the resulting structure are collectively illustrated in FIGS. 26A, 26B, 26C, and 26D.

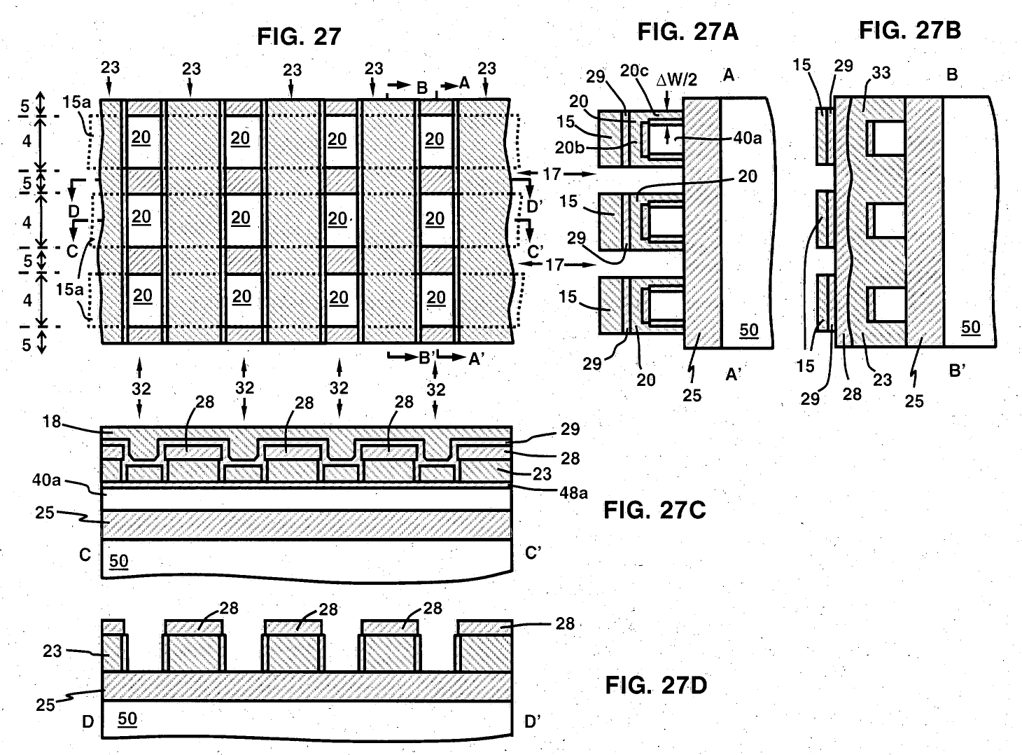

The structure is further processed by forming a second insulating layer 29 such as oxide with thickness on the order of about 50 Å to 300 Å (preferably 100 Å to 200 Å) using conventional deposition technique or thermal oxidation process. The second insulator 29 can also be formed in composite layers comprising more than two different dielectrics (e.g. oxide-nitride-oxide tri-layers). For process simplicity, an oxide layer of HTO (high temperature oxide) is chosen here as the insulating layer 29 for illustration purpose. Next, an electrically conductive layer 18 with thickness on the order of about 500 to 4000 Å is deposited over the structure. The conductive layer 18 can be made of, for example, polysilicon, metalized polysilicon such as W-polycide, or metals, and is to be used to form the control gate block 15 of the memory cells 100c. For a preferred embodiment, W-polycide on a polysilicon is chosen here for the layer 18 with the topography preferably planar. Thereafter, a photo-resist is formed over the conductive layer 18 followed by a masking step using conventional photo-lithography technique to selectively remove the photo-resist leaving a plurality of photo-resist stripes over the conductive layer 18 and oriented in the first direction. Each of the photo-resist stripes is wider than the silicon block 40a by a difference ΔW generally in the range of about 0.05 to 0.1 Mm, and is properly aligned thereto. The process is continued by using an anisotropic etch process, such as RIE, to remove the exposed W-polycide and polysilicon layer 18 until the oxide layer 29 is observed, which acts as an etch stop. A controlled oxide etch followed to remove the exposed oxide layer 29 until the underlying second polysilicon 19 is observed, which acts as an etch stop. A polysilicon etch then followed to removed the exposed polysilicon 19, which is in the polysilicon stripe regions 19b, until the insulating layer 25 is observed, which acts as an etch stop. The portions of conductive layer 18, oxide layer 29, and polysilicon 19 in the polysilicon stripes 19b still underneath the remaining photo-resist are unaffected by this etch process. This etching step forms a plurality of floating gate 20 and a plurality of control gates 15 each disposed over and insulated from one of the floating gates 20 (FIG. 27A). The floating gates 20 are formed with folded architecture self-aligned to the control gates 15, and hence have same dimension on width (defined along the second direction). Each of the floating gates 20 thus formed comprises a pair of vertical portions 20c (first and second sections), each laterally adjacent to one of the sidewalls of one of the silicon blocks 40a, and a horizontal section 20b (third section) over the top of the one silicon block 40a. The etch also forms a plurality of spaced apart word lines 15a, which are generally parallel to one another and extend in the first direction with a trench stripe 17 between each pair of adjacent word lines 15a (FIG. 27). Each of the word lines 15a extends continuously across the SL/BLs 23 and the trench stripe regions 32 to connect together a row of the control gates 15 in that row of memory cells. The space between adjacent word lines 15a can be as small as the smallest lithographic feature of the process used. The width of each of the word lines 15a can be however slightly larger than the smallest lithographic feature by a value of ΔW (i.e. ΔW/2 per side, as shown in FIG. 27A). The remaining photo-resist is then removed using conventional means. The top plan view of the resulting structure is shown in FIG. 27. The cross-sectional views of the resulting structure are collectively illustrated in FIGS. 27A, 27B, 27C, and 27D.

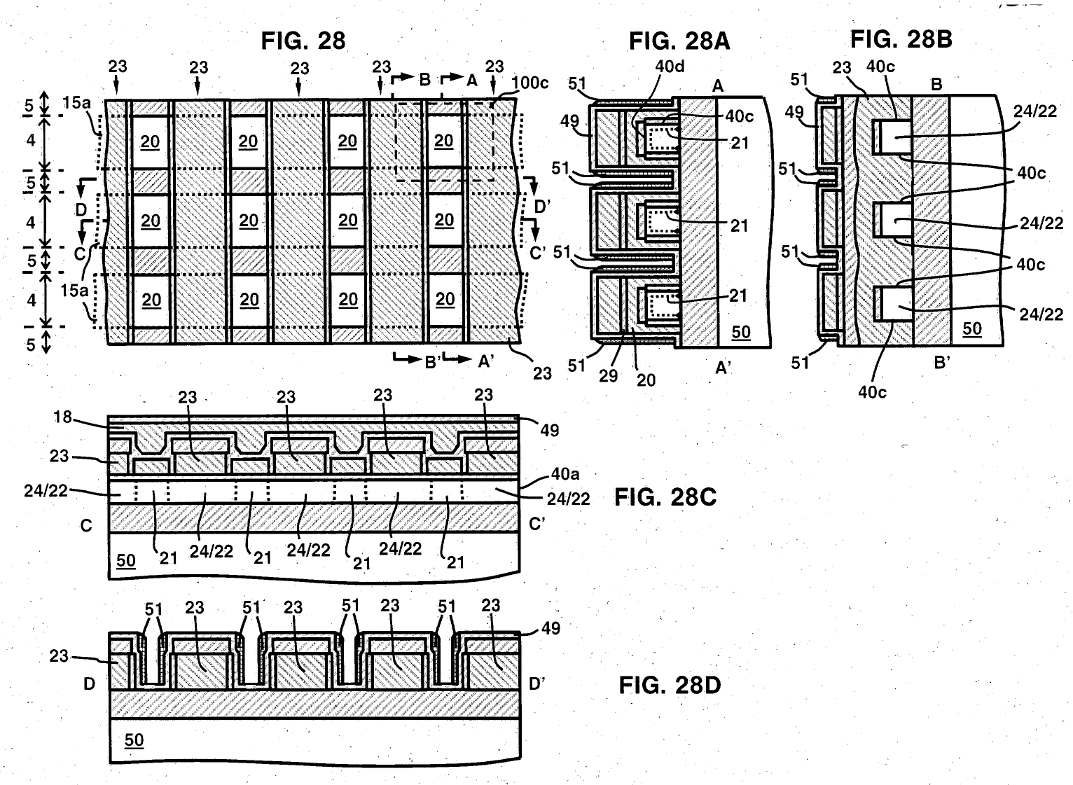

The process is further continued by forming an insulating layer 49 over the entire structure. The insulating layer can be an oxide layer of thickness about 100 to 200 Å formed by using conventional oxidation or deposition techniques. In the preferred embodiment, a deposited HTO film is used for process simplicity. Oxide layer 49 joins with the oxide regions 29 in forming insulation layers encapsulating each of the floating gates 20 (FIG. 28A). The process is followed by forming optional spacers 51 along sidewalls of control gates 15 and floating gates 20. The spacers can be made of any insulating material (e.g. oxide or nitride). In the preferred embodiment, spacers 51 are formed of nitride in the same way as described hereinbefore with respect to FIG. 5A. The top plan view of the resulting structure is shown in FIG. 28, wherein the border of one of the memory cells 100c is shown. The memory cells 100c are arranged along with the floating gates 20 in an array of rows extending in the first direction and columns in the second direction. In each of the silicon line blocks 40a of the resulting structure, the portions of 40a under the SL/BLs 23 correspond to the first and second regions 24/22 of the memory cells 100c, as shown in FIG. 28C. Each of the first and second regions 24/22 is electrically contacted by the SL/BLs 23 through the sidewalls 40c of each of the silicon blocks 40a, as shown in FIG. 28B. Each of the channel region 21 is defined in between a pair of the first and second regions 24/22, as shown in FIG. 28C, and are formed under the surfaces of the top 40d and sidewalls 40c of the silicon blocks 40a, as shown in FIG. 28A. The memory cell is a three-dimensional structure. During cell operations, the channel carriers flow from the first region 24 to the second region 22 along the channel in a direction orthogonal to that of FIG. 28A.

The cross-sectional views of the resulting structure are collectively illustrated in FIGS. 28A, 28B, 28C, and 28D. The structure can be further processed by following conventional backend process steps as described in the first embodiment to form a passivation and bonding pads atop the structure.

The operation method on cell 100c is the same as that in the first embodiment. The memory cell array formed thereby has the same advantages as outlined in the first embodiment.

Fourth Embodiment

The embodiments disclosed hereinbefore can be extended to nonvolatile memory cells of architecture using Ballistic-Charge-Injection as the mechanism for program and for erase operations. This can be done by adding a ballistic-charge injector into one of the embodiments on memory cells of the present invention. The memory cell 100d shown in FIG. 1D is provided to demonstrate this effect on memory cell 100b of the first embodiment, wherein cell-is built in a silicon substrate, as shown in FIG. 1B. A manufacturing method forming memory cell of this type is illustrated hereinafter.

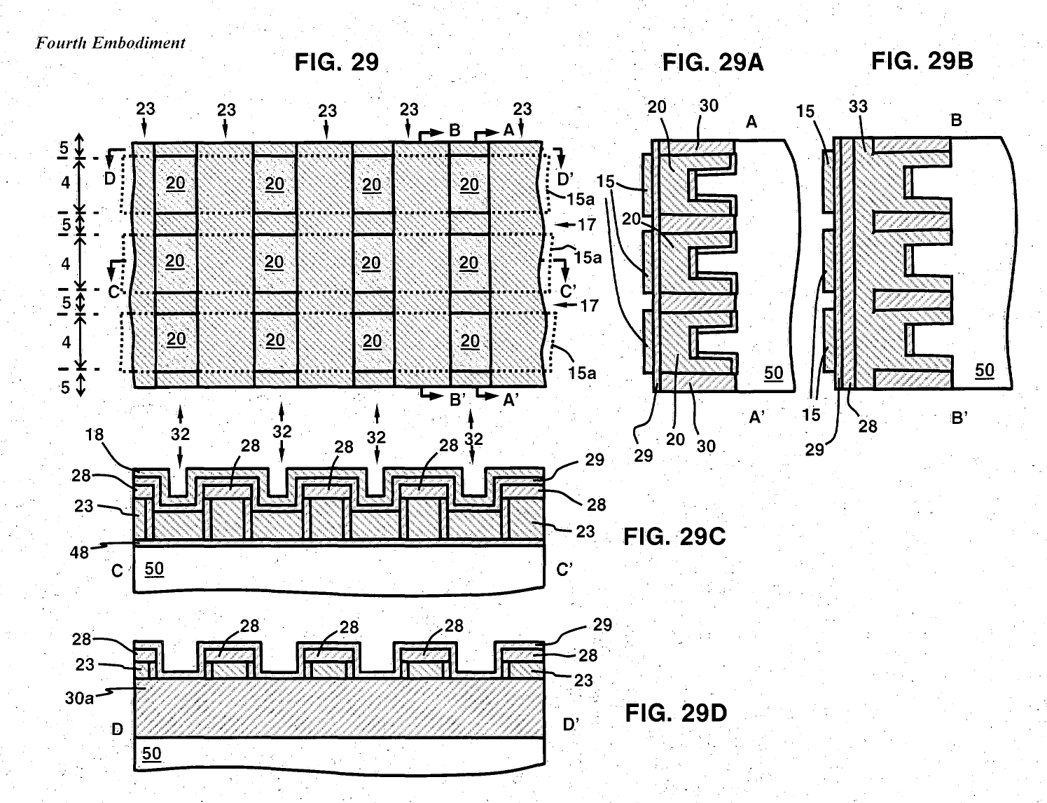

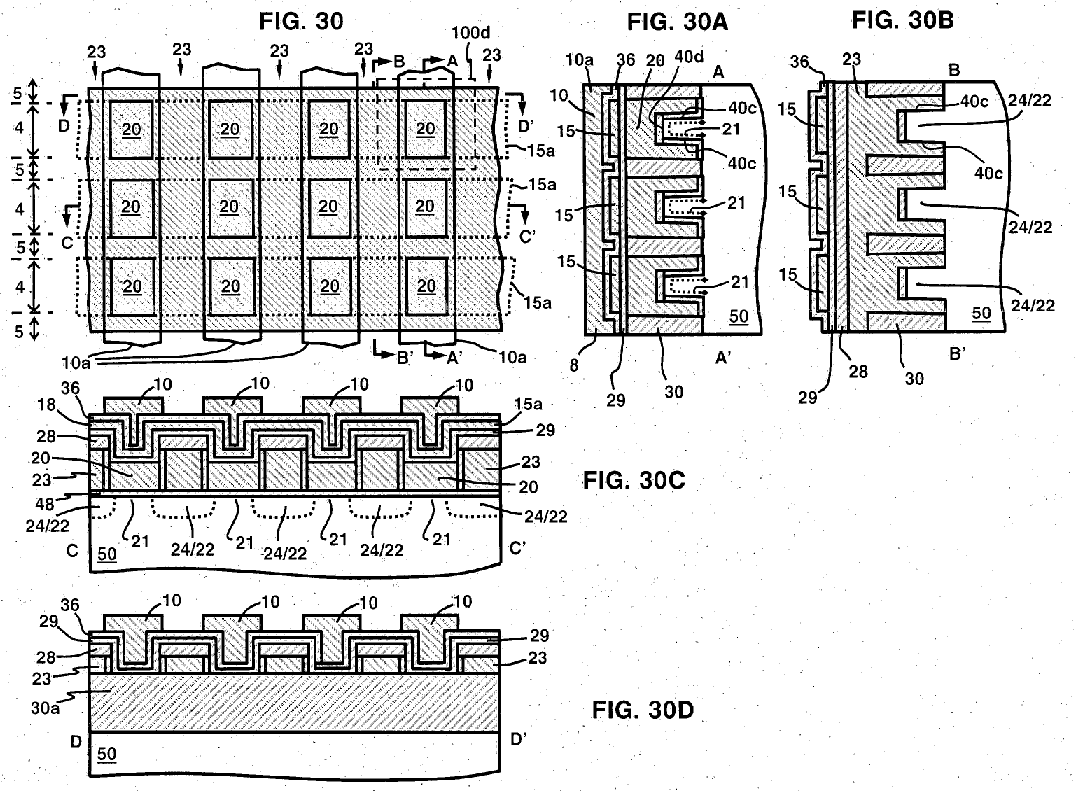

FIGS. 29 to 30 and figures of associated cross-sectional view illustrate manufacturing method for the fourth embodiment for forming the memory cell structure 100d, which is similar to that illustrated in FIG. 1B but utilizing Ballistic-Charge-Injection for cell operations. This fourth embodiment follows the same process steps as provided in the second embodiment till the completion on the structure in FIG. 20, wherein the floating gates 20 are arranged in an array of rows each in between an adjacent isolation regions 5, and in an array of columns each in between an adjacent SL/BL regions 23. Immediately following the structure in FIG. 20, the deviations on process start and are described hereinafter.

A second insulating layer 29 is formed over the structure. The second insulating layer 29 can be, for example a single layer of oxide with thickness about 100 to 200 Å, formed by using thermal oxidation or deposition techniques. The insulator 29 can be also in composite layers 5 form (e.g. oxide-nitride-oxide). Oxide (deposited HTO film) is chosen here as illustration.

An electrically conductive layer 18 with thickness about 400 to 1000 Å is formed over the second insulating layer 29. The conductive layer 18 can be formed of any conductive materials, for example, polysilicon, W-polycide or metals, and is to be used to form the control gates 15 of the memory cells. In a preferred embodiment, polysilicon is used for the conductive layer 18 and is preferably heavily doped in p-type impurity via in-Situ method or a subsequent implant. The topography of the polysilicon layer follows the topography prior to the deposition.

Thereafter, a photo-resist is formed over the polysilicon layer 18 followed by a masking step using conventional photo-lithography technique to selectively remove the photo-resist leaving a plurality of photo-resist stripes over the polysilicon layer 18 and oriented in the first direction. Each of the photo-resist stripes is properly aligned to a row of floating gate regions 20. The process is continued by using an anisotropic etch process, such as RIE, to remove the exposed polysilicon layer 18 until the oxide layer 29 is observed, which acts as an etch stop. The etch also forms a plurality of spaced apart word lines 15a, which are generally parallel to one another and extend in the first direction with a semi-recessed trench stripe 17 between each pair of adjacent word lines 15a. Each of the word lines 15a extends continuously across the SL/BLs 23 and the trench stripe regions 32 to connect together a row of control gates 15 in that row of memory cells. The space between adjacent word lines 15a and the width of each of word lines 15a can be as small as the smallest lithographic feature of the process used. The portions of polysilicon layer 18 still underneath the remaining photo-resist are unaffected by this etch process. The remaining photo-resist is then removed using conventional means. The word lines 15a are aligned to the floating-gates 20 on the same row. The top plan view of the resulting structure is shown in FIG. 29. The cross-sectional views of the resulting structure are collectively illustrated in FIGS. 29A, 29B, 29C, and 29D.

The structure is further processed by forming a third insulating layer 36 with thickness on the order of about 40 Å to about 100 Å using conventional deposition techniques or thermal oxidation process. The insulator 36 can also be made of insulating materials such as a high quality oxide, nitride or oxynitride. Other than in single layer form, the insulating layer 36 can be also formed in composite layers comprising more than two different dielectrics (e.g. oxide-nitride-oxide tri-layers). In the preferred embodiment, the insulator 14 is preferably an oxynitride layer with fractional oxide approximately equal to 82%. This can be done, for example, by a thermal oxidation step followed by a thermal nitridation using well known technique such as Remote-Plasma-Nitridation to form insulator encapsulating any exposed portions of the control gates 15.

Next, an electrically conductive layer 8 with thickness on the order of about 1500 Å to about 3000 Å is deposited over the structure. The layer 8 can be formed of ally conductive materials, for example, polysilicon, W-polycide or metals, and is to be used to form the tunneling gates 10 of the memory cells. In the preferred embodiment, a heavily doped polysilicon is used for the conductive layer 8 and is preferably doped in p-type via in-Situ method or a subsequent ion implantation. The topography of the polysilicon layer is preferably planar. Thereafter, a photo-resist is formed over the polysilicon layer 8 followed by a masking step using conventional photo-lithography technique to selectively remove the photo-resist leaving a plurality of photo-resist stripes over the polysilicon layer 8 and oriented in the second direction. An anisotropic etch process, such as RUE, followed to remove the exposed polysilicon layer 8 until the oxide layer 36 is observed, which acts as an etch stop. The etch forms a plurality of tunneling gates 10 arranged in an array of rows extending in the first direction and columns in the second direction. Each of the tunneling gates 10 overlaps with one of the control gates 15 at an overlapping region, where at least a portion of one of the floating gates is disposed thereunder. The etch further forms a plurality of spaced apart tunneling lines 10a or cathode-lines used for supplying tunneling charges for ballistic charges injection in cell operations. The tunneling lines 10a are generally parallel to one another and extend in the second direction with each tunneling line 10a extends continuously across the active and isolation regions 4/5 to connect together a column of tunneling gates 10 in that column of memory cells. The space between adjacent tunneling lines 10a and the width of each of tunneling lines 10a can be as small as the smallest lithographic feature of the process used. The portions of polysilicon layer 8 still underneath the remaining photo-resist are unaffected by this etch process. The remaining photoresist is then removed using conventional means. Each of the tunneling lines is aligned to a column of floating gates 20 in that column of memory cells through proper masking alignment during the photo-lithography step. It is noted that each of the tunneling gates 10 is insulated from the underlying control gates 15 by the third insulating layer 36 to form a sandwiched tri-layers tunneling structure used as the injector for ballistic charges injection. The tri-layers structure of the preferred embodiment, namely a p-type polysilicon/third insulator/p-type 5 polysilicon structure, has the advantage of supplying both types of charges (i.e. electrons and holes) via the same tunneling gate 20 for ballistic charges injection. Furthermore, in the preferred embodiment, using oxynitride with fractional oxide at about 82% for the third insulator has the advantage of permitting both types of charges transporting therethrough at a similar rate in both forward and reverse directions. This tri-layer layer structure has the advantage on preventing one type of carrier from dominating the other type while providing bipolar charges injection function in a single electrode. The structure of the specific embodiment hence provides an improvement over US 2001/0019151 A1.

The top plan view of the resulting structure is shown in FIG. 30, wherein the border of one of the memory cells 100d is shown. The memory cells 100d are arranged along with the floating gates 20 in an array of rows extending in the first direction and columns in the second direction. In each of the silicon line blocks 40a of the resulting structure, the portions of 40a under the SL/BLs 23 correspond to the first and second regions 24/22 of the memory cells 100d, as shown in FIG. 30C. Each of the first and second regions 24/22 is electrically contacted to the SL/BLs 23 through the sidewalls 40c of each of the silicon blocks 40a, as shown in FIG. 30B. Each of the channel region 21 is defined in between a pair of the first and second regions 24/22, as shown in FIG. 30C, and are formed under and adjacent to the surfaces of the top 40d and sidewalls 40c of the silicon blocks 40a shown in FIG. 30A. The cross-sectional views of the resulting structure are collectively illustrated in FIGS. 30A, 30B, 30C, and 30D. The memory cell is a three-dimensional structure. During cell operation, the channel carriers flow from the first region (or source region) 24 to the second region (or drain region) 22 along the channel in a direction orthogonal to that of FIG. 30A.

Similar to other embodiments, the structure can be further processed by following conventional backend process steps as described in the first embodiment to form a passivation and bonding pads atop the structure.

The method and memory cell array formed in this embodiment have several advantages. First, the first and second regions 24/22 of each memory cell are formed to self-align to the source/drain lines 23, which can be formed in the smallest feature size of a process technology. Second, the floating gates 20 are formed adjacent and self-aligned to a pair of adjacent source/bit lines 23, which can be formed in the smallest feature size on spacing of a process technology. Third, in the cross-section along the column direction (FIG. 30A), each of the floating gates 20 is formed self-aligned and spaced apart from an adjacent one by one of the insulator blocks 30, which can be formed in the smallest feature size of a process technology. Fourth, the floating gate 20 is folded around the silicon block 40a to form a three-dimensional fringing field, which enhances the control of floating gate on surface potential in channel region and hence suppress the drain-to-source punch-through during cell operations. Thereby, the structure permits further cell scaling along the Length direction. Fifth, due to the folded floating gate architecture, the present invention presents cell structures with wider channel, permitting cell scaling without sacrificing the channel current. This is because the channel current is linearly proportional to the channel width. For memory cells of this invention, other than the plane component observed in conventional memory cells, the cells also provide additional channel components contributed from the sidewalls 40c substantially perpendicular to the substrate, thus increasing the effective channel width without enlarging the cell Width and area. Finally, the memory structure of the present invention is formed by using a relatively low number of masking steps, which is particularly advantageous for manufacturing. With the folded cell architecture and the self-aligned method, the size of each cell is the minimum pitch, defined as the sum of width and space, in each direction. Therefore, the memory cell 100d can occupy an area of 4F², where “F” is the minimum feature size of a process technology. For example, cell areas of approximately 0.0676 μm and 0.04 μm can be achieved by the present invention using 0.13 μm and 0.10 μm technology generations, respectively.

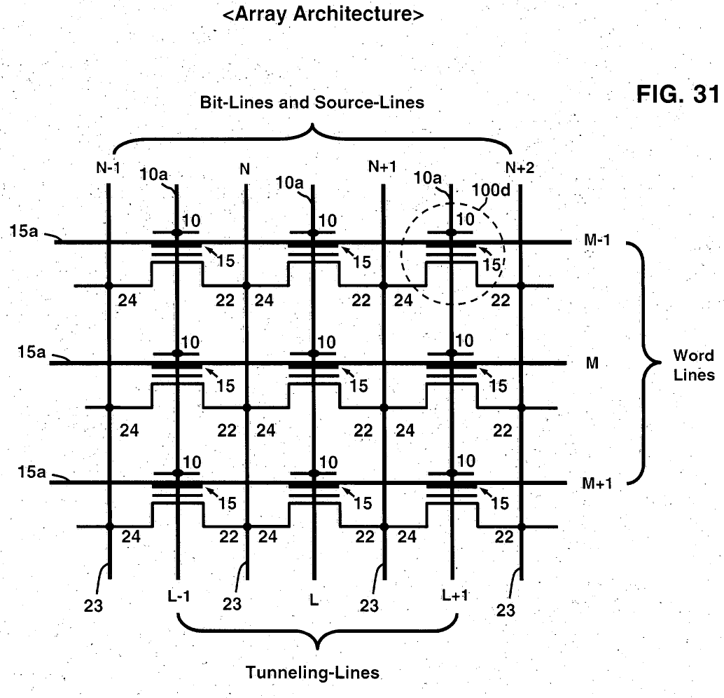

The memory cells of this embodiment is demonstrated in memory array arranged in a NOR configuration. FIG. 31 shows the array architecture in schematic diagram corresponding a segment of the structure shown in FIG. 30, wherein each of the first and second regions 24/22 correspond to the source and drain regions of one of the memory cells. The control gate 15 of each of the memory cells 100d in the same row are connected together through one of the word lines 15a. Thereby, the word line M+1 connects the control gates 15 of each of the memory cells in the lowermost row shown in FIG. 31. Similarly, the tunneling gate 100of each of the memory cells 100d in the same column are connected together through one of the tunneling lines 10a. Thereby, the tunneling line L−1 connects the tunneling gates 10 of each of the memory cells in the leftmost column shown in FIG. 31. Each of the bit lines 23 connects all the second regions of memory cells in the same column. Thereby, the bit line N connects the drain region 22 of each of the memory cells in the leftmost column shown in FIG. 31. Since the array demonstrated in this example used the virtual ground array architecture, the bit line N for memory cells on the leftmost column also functioned as the source line N for memory cells on the adjacent column (i.e. the center column in FIG. 31). Those of skill in the art will recognize that the term source and drain may be interchanged, and the source and drain lines or source and bit lines may be interchanged as well. Further, the word line is connected to the control gate of the floating gate memory cell. Thus, the term control gate, control gate block or control gate line may also be used interchangeably with the term word line.

The NOR array shown in FIG. 31 is a well-known array architecture used as an example to illustrate the array formation using memory cells of the present invention. It should be appreciated that while only a small segment of array region is shown, the provisions in FIG. 31 illustrate any size of array of such regions. Additionally, it should be appreciated by those of ordinary skill in the art that the memory cells can be applied to other type of NOR array architectures. Furthermore, the memory cells may be arranged in memory array in either NOR or NAND configuration or a combination thereof.

Memory Cell Operation

The operation of the memory cells will now be described below with reference to schematics in FIG. 31 and views in FIGS. 30 and 30A. For PROGRAM operation, one of the bit cells in the memory array is first located by selecting one of the word lines 15a (e.g. line “M−1”), one of the tunneling lines 10a (e.g. line “L+1”), and a pair of adjacent source-lines/Bit-lines 23 (e.g. lines “N+1” and “N+2”). The selected bit cell 100d is shown in dashed line in FIG. 31 (also shown in FIG. 30). With a bit cell 100d thus selected, various embodiments on operations of the memory cell will now be described hereinafter.

Embodiment No. 1 for Cell Operation

Program

When a selected memory cell is desired to be programmed, a first type of charges (e.g. electrons) is injected into the floating gate region 20 of that cell using the ballistic charge injection (BCI) mechanism. This can be done by first applying a small voltage (e.g. 2.0 V) to the control gate 15 through the word line “M−1” of the selected cell. A negative voltage is then applied to the tunneling gate 10 through the tunneling line “L+1” at a level where the relative difference to the control gate 15 is in the vicinity of the voltage allowing charges to surmount the conduction band barrier height of the second insulating layer 29. In accordance with the prefer embodiment on tri-layer structure disclosed in FIG. 30, the conduction band barrier height for electron charges is about 4 eV, and hence a typical voltage to the tunneling gate 10 can be approximately from −2.1 to −2.5 volts. A positive voltage, on the order of about 0 to about 0.9 volts, can be applied to its floating gate region 20 through voltage capacitive coupled from the first region 22 (or source region), and the second region 24 (or drain region). The voltage on the source/drain regions 22/24 can be applied through selecting SL/BLs “N+1” and “N+2” of the selected cell. The bias configuration on the selected cell permits electrons emanating from the tunneling gate region 10 to tunnel through the third insulating layer 36 toward the control gate 15. As the electrons reach the control gate 15, they will transport at a high energy with a portion of them being able to transport through this region via the ballistic transport mechanism, which preserves their energy while reaching the interface between control gate 15 and the second insulating layer 29 (referring to FIG. 30A). The high energy allows the electron carriers surmounting the barrier height of the insulator 29, moving into and transporting through it and onto, the floating gate 20. The ballistic transport is usually made possible by controlling the thickness of the control gate 15 to a range similar to the electron mean-free-path of the material in that region. Ground potential is applied to the source/drain regions 24/22 for memory cell columns not containing the selected memory cell. Ground potential is applied to the control gates 15 for memory cell rows not containing the selected memory cell, and is applied to the tunneling gates 10 for memory cell columns not containing the selected memory cell. Thus, only the memory cell in the selected row and column is programmed.

The injection of electrons onto the floating gate 20 will continue until a blocking effect on the ballistic electrons taking place. The blocking effect is due to the rising of the energy bands in the floating gate 20, which is equivalent to the effect of lowering the floating gate potential as electron charges accumulated thereon. As a result, an energy barrier in the insulator 29 is formed and will continue to increase as more ballistic electrons are injected into and accumulated on the floating gate 20. The reduced charge on the floating gate 20 will decrease the electron flow from the tunneling gate 10 onto the floating gate 20 until to a point the barrier height is high enough to completely block ballistic electrons transport thereunto. The charge blocking mechanism is highly voltage-sensitive. In other words, its current dependence on voltage-is more sensitive than that usually observed in the Fowler-Nordheim tunneling. Further, the insulator 29 is typically with thickness of about 80 angstrom or thicker, where the voltage-less-sensitive charge tunneling, namely the direct-tunneling phenomenon, is not permitted. These effects provide an effective self-limiting mechanism for ballistic charge injection. It thus provides a method permitting charges be injected onto floating gate at a fine incremental level through incrementally adjusting the bias at regions (such as the drain 22) adjacent to the floating gate 20. The mechanism thus permits multi-level states storage.

Erase

The erase of a selected memory cell is typically done by reversing the polarity of the bias applied to each of the nodes shown in the program operation. Specifically, a second type of ballistic charges (e.g. holes) is injected into the floating gate region 20 of the selected cell using the BCI mechanism. This can be done by first applying a small voltage (e.g. −2.0 V) to its control gate region 15. A positive voltage is then applied to the tunneling gate 10 at a level where the relative difference to the control gate region 15 is in the vicinity of the voltage allowing hole-charges to surmount the valence band barrier height of the second layer 29. The bias at these nodes can be delivered through selecting word line, tunneling line, and SL/BLs of the selected cell at the same procedure as described in the “Program” operation. In accordance with the prefer embodiment on the tri-layer structure disclosed in FIG. 30, the valance band barrier height for hole charges is about 4.0 eV, and hence a typical voltage to the tunneling gate 10 can be on the order of approximately +2.1 to +2.5 volts. Then a negative voltage, on the order of 0 to −0.9 volts, can be applied to its floating gate region 20 through voltage capacitive coupled from the drain region 22, and the source region 24. Under this bias condition, holes on the tunneling gate 10 are induced through quantum mechanical tunneling mechanism to tunnel through the third insulator layer 36 thereunder. As the holes reach the control gate 15, they will transport at a high energy with portions of them being able to transport through this region via the ballistic transport mechanism, which preserve their energy while reaching the interface between the control gate 15 and the insulating layer 29. The high energy allows hole-carriers surmounting the valence-band barrier height of insulator 29, moving into and transporting through it and onto the floating gate 20, neutralizing the electron charges wherein. The ballistic hole carriers will continue making their way in and eventually leaving the floating gate 20 be positively charged before a self-limiting mechanism taking place. The self-limiting mechanism for hole-charges is a similar one as in the program operation for electron charges. The ballistic hole transport efficiency, defined as the ratio of the holes reaching the floating gate 20 to the holes emanating from the tunneling gate 10, can be generally enhanced by controlling the film thickness of control gate 15 to a range similar to the mean-free-path of hole-charges in material used for the control gate 15. Ground potential is applied to the source regions 24 and drain regions 22 for memory cell columns not containing the selected memory cell. Ground potential is applied to the control gates 15 for memory cell rows not containing the selected memory cell, and is applied to tunneling gates 10 for memory cell columns not containing the selected memory cell. Thus, only memory cell in the selected row and column is erased.

For memory cells in accordance with the present inventions, it should be noted that both program and erase operations can be done with absolute bias at a level less than or equal to 2.5V. Furthermore, the erase mechanism and cell architecture enable the individually erasable cells feature, which is ideal for storing data such as constants that required periodically changed. The same feature is further extendable to small group of such cells which are erased simultaneously (e.g. cells storing a digital word, which contains 8 cells). Additionally, the same feature is also further extendable to such cells which are erasable simultaneously in large group (e.g. cells storing code for software program, which can contain 2048 cells configured in a page, or contain a plurality of pages in a block in array architecture).

Finally, to read a selected memory cell, ground potential is applied to the source region 24 through one of the SL/BLs 23 (e.g. line “N+1”) of the selected cell. A read voltage of approximately +1 volt is applied to its drain region 22 through the other SL/BLs 23 (e.g. line “N+2”) of the selected cell, and approximately 2.5 volts (depending upon the power supply voltage of the device) is applied to the control gate 15 through the word line 15a (e.g. line “M−1”) of the same cell. Other lines in the array are at ground potential. If the floating gate 20 is positively charged (i.e. the floating gate is discharged of electrons), then the channel region 21 is turned on. Thus, an electrical current will flow from the source region 24 to the drain region 22. This would be the “1” state.

On the other hand, if the floating gate 20 is negatively charged, the channel region 21 is either weakly turned on or is entirely shut off. Even when the control gate 15 and the drain region 22 are raised to the read potential, little or no current will flow through channel region 21. In this case, either the current is very small compared to that of the “1” state or there is no current at all. In this manner, the memory cell is sensed to be programmed at the “0” state. Ground potential is applied to the source regions 24, drain regions 22, and control gates 15 for non-selected columns and rows so only the selected memory cell is read. For both selected and non-selected memory cells, ground potential is applied to the substrate region 50.

The memory cell can be formed in an array with peripheral circuitry including conventional row address decoding circuitry, column address decoding circuitry, sense amplifier circuitry, output buffer circuitry and input buffer circuitry, which are well known in the art.

The cell operation and the memory cell architecture of the present invention is advantageous because it does not require high voltages (e.g. 2.5V or higher) for cell operations, and hence remove requirements on high-voltage infrastructures outlined earlier and avoid issues therein. Another important feature of the present invention is the provision of a tunneling gate 10 over a control gate 15 with a floating gate 20 underlying the overlap between regions 10 and 15. The provision allows a charge injection scheme where electrons or holes can be emanated from a tunneling gate 10 above the silicon substrate and are transported along a downward direction into floating gate 20 thereunder.

The “top-down” injection scheme in the present invention provides a main advantage over conventional arts. First, the program efficiency is greatly enhanced by “aiming” the ballistic charge carriers at the floating-gate 20. In conventional programming schemes, the electrons transport along the channel region in a path parallel to the floating gate, where a relatively small number of the electrons become heated and are injected onto the floating gate. The program efficiency (number of charges injected compared to total number of charges supplied) is estimated at about 1/1000 to about 1/1,000,000. However, in the present invention, because the “top-down” injection scheme, high energy carriers are ‘aimed’ directly at the floating gate, the program efficiency is estimated to be closer to about 1/100, where almost most of the charges are injected onto the floating gate. Secondly, through out the cell operations, the highest voltage (e.g. 2.5V) appears only to regions above the silicon surface level (such as the control gate region 15 and the tunneling gate region 10). In other words, none of the regions under the silicon surface where metallurgical junctions are involved (e.g. source regions 24 and drain regions 22) will ever experience the highest voltage provided in cell operations. This is because in the present invention, both source regions 24 and drain regions 22 have a principle role on the read operation, which is performed at a relative low voltage. Though regions 24/22 are involved in program and erase operations, their role are primarily to couple a small amount of voltage (˜0 to 1V) to the floating gate 20, and have no involvement whatsoever on high voltage effect such as generating or supplying high energy carriers.

Being able to keep regions with metallurgical junctions at a relative low voltage through out the cell operations provides a unique feature to the present invention. The feature not only provides a significant advancement over prior arts, but brings several additional advantages hereto. First, the scaling constraints on cell height as outlined hereinbefore is removed, therefore further scaling on cell dimension using smallest design rule in future generation technologies is possible. Secondly, the hot carrier effect associated with a metallurgical junction field and its degradation and damage to the insulator 48 adjacent thereto are avoided. This is in a clear contrast to the damage effect in prior arts, where cell programming is done by heating up electrons through applying a high voltage at one of the junctions, which inevitably introduces high field across insulator adjacent to the floating gate and results in damage therein. Furthermore, due to the relatively smaller difference on voltage between the floating gate 20 and its surrounding regions (e.g. drain 22), the field stress effect on the insulator 48 therebetween are largely suppressed. This advantage is of particular importance to charge retention and reliability for nonvolatile memory cells.

Cell Disturb

As memory cells 100d are placed in an array environment, cell state can be unintentionally changed during the useful lifetime of usage due to cumulative disturbance introduced while conducting cell operations (i.e. program, erase, and read) throughout other cells that are within a same memory array. This embodiment provides memory cells immune to this issue. For example, for electrons or holes to surmount the barrier height of the insulator 48, which is adjacent to the floating gate 20 and the drain region 22, the carriers have to be heated up by the junction field of a drain region 22 to a kinetic energy higher than the barrier height (about 3.1 eV for electrons and 4.6 eV for holes) of the insulator 48. Being able to keep relatively low voltage (e.g. about 2.0 to about 2.5V) at the drain 22 (and other electrodes with metallurgical junctions) enable the present invention to effectively prevent electrons or holes gaining energy higher than the barrier height of the insulator 48. In other words, in terms of disturb by a junction field, the cell architecture provided herein permit bias scheme producing negligible disturb on non-selected cells during an erase, a read or a program operation on a selected cell.

Additionally, the ballistic charge injection scheme in memory cells of the present invention also exhibits greatly decreased cell-disturb effect. There are several cases can be considered to demonstrate this effect. First, the worse case of a read disturb condition happens as the floating gate 20 is in an erase state (i.e. the floating gate 20 is in a neutral or a positively charged state). Under this condition, a small amount of ballistic electrons, which are induced by the control gate 15, can transport through the control gate 15 to arrive at the interface between region 15 and insulator 29. However, those electrons will not be able to surmount the barrier height thereat (about 4 eV) due to the fact that their energy is limited by the relative lower bias (about +2V) between, control gate 15 and tunneling gate 10 during a read operation. As a result, the carriers will be blocked from reaching the floating gate 20, thereby-having no effects whatsoever on the charge state therein. Secondly, the worse of an erase disturb condition can happen to non-selected cells with floating gates 20 in a program state (i.e. the floating gate 20 is in a negatively charged state). Under this condition, a small amount of ballistic holes, which are induced by the control gate 15, can transport through the control gate 15 to arrive at the interface between region 15 and insulator 29. However, similar to the ballistic electrons in the first case, those holes will not be able to surmount the barrier height thereat (about 4 eV) due to the fact that their energy is limited by the relative lower bias (about 2V) between the control gate 15 and the tunneling gate 10 during an erase operation. As a result, the hole-carriers will be blocked from reaching the floating gate 20, thereby having no effects whatsoever on the charge state therein.

Furthermore, the memory cell of the present invention exhibits greatly reduced cell disturb that caused by the capacitive coupling on voltage drop across the insulator 29. The worse condition on cell disturb due to this effect is for memory cell with floating gate 20 in the programmed state (i.e. floating gate negatively charged). Since the cell 100d can be designed with an equally distributed capacitive coupling between the floating gate 20 and other electrodes (e.g. drain 22, source 24 etc), the capacitive coupling between the control gate 15 and the floating gate 20 is about 20%; This effect in together with the lower-voltage on the control gate 15 during a read operation, can result in a voltage drop between the floating gate 20 and the control gate 15 be as low as 1.5 to 2.5V, where charge leakage through insulator 29, which is through Fowler-Nordheim tunneling, is negligible.

Overview the disturb effects and mechanisms outlined herein, in general, both the cell operation conditions and the cell capacitances of memory cell hereof can be optimized through cell design such that the disturb effects on floating gate charges during the lifetime usage of a memory product be kept at a level low enough to prevent flipping cell state from a “0” state to a “1” state or vice versa.

Embodiment No. 2 for Cell Operation

In the embodiment No.2 for cell operation, the method for programming the memory cell 100d can be provided as follows:

When a selected memory cell is desired to be programmed, electrons can be injected through CHEI mechanism by applying a voltage (e.g. 3V) to the WL to couple enough voltage into the floating gate 20 to turn on the channel 21 of the selected cell while the source is at ground and the drain is at a high voltage (e.g. 4V). During the CHEI operation, a negative potential is applied to the tunneling gate region 10 of the selected cell. The voltage at the tunneling gate can be set at a value permitting ballistic electrons be injected onto the floating gate. For example, for the tri-layers structure provided in the preferred embodiment for the ballistic charge injector, the voltage applied at the tunneling gate 10 can be about −1.5 to about 2V. Therefore, in addition to the CHEI action, this bias configuration also permits same type of charges (i.e. electrons) be emanated from the tunneling gate region 10 and be injected onto the floating gate region 20 of that cell at the same time through BCI mechanism. The CHEI mechanism permits electrons entering onto floating gate along a “bottom-up” path from the channel region, whereas the BCI mechanism permits electrons entering the floating gate along a “top-down” path from the tunneling gate region as aforementioned. This provides a “double” injection scheme, which has the advantage on increasing the program efficiency, and hence shortening the program time of a program event. Ground potential is applied to the drain regions 22 and tunneling gates 10 for memory cell columns not containing the selected memory cell. Current at source regions 24 are kept below at a minimum level (e.g. about 10⁻¹² amperes or lower) for memory cell columns not containing the selected memory cell. This can be done by, for example, leaving the source lines of those columns open. Ground potential is applied to the control gates 15 for memory cell rows not containing the selected memory cell. Thus, only the memory cell in the selected row and column is programmed.

The “double-injection” program scheme can be combined with the BCI erase scheme, which injects ballistic holes onto floating gate, to operate memory cell 100d for storing a “1” or a “0” state, as defined hereinbefore.

It should be noted that the Voltage in the bias configuration herein described is for memory cell 100d with the tri-layers structures described in the preferred embodiment for the ballistic injector, and can be optimized to suit for the injector of other types without departing the invention concepts herein.

Embodiment No. 3 for Cell Operation The embodiment No. 3 on operating the memory cell 100d is provided by considering CHEI for program and BCI using holes for erase. Here, the BCI for erase injects ballistic holes onto floating gate to neutralize the electrons therein. This embodiment provides solution for issues encountered in memory cell 100d where a strong hole-carriers back-flow (i.e. from control gate to tunneling gate) occurs during a ballistic electron injection event for program using BCI mechanism, as provided in the embodiment No. 1 for cell operation. This issue can be encountered in many different ways. For example, it occurs when a p+ polysilicon/nitride/p+ polysilicon tri-layers structure, which corresponds to regions of tunneling gate/third insulator/control gate, is employed as the ballistic charge injector in memory cell 100d. The issue can be understood by considering the barrier heights for electrons and for holes in the tri-layer injector. The barrier height for electrons at a p+ polysilicon/nitride interface is about 3.2 eV, and the barrier height for holes is about 2.1 eV. Because the much higher barrier height for electrons than for holes, it prevents electron carriers from tunneling through the tri-layer structure at a similar rate as that for holes. In this case, the total current flowing through the tri-layer structure is dominated by the hole current at a range approximately 1 million times of the electron current. Therefore, when using ballistic electrons for program, a relatively high electrical current between the control gate 15 and the tunneling gate 10 is therefore needed to inject a significant number of electrons onto the floating gate 20 of memory cell 100d. This high hole current can severely limit the electron injection capability achieving a desired voltage range, hence an energy range, due to the loading on charge-pump circuits. Therefore, the high hole current places a practical limit on the injection of ballistic electrons onto the floating gate, making the program operation using BCI be difficult.

For this embodiment, the cell 100d is program through CHEI mechanism only. The bias configuration for programming a selected memory cell can be set, for example, by applying a voltage (e.g. 3V) to the WL to couple enough voltage into the floating gate 20 to turn on the channel 21 of the selected cell while the source is at ground and the drain voltage is at a high voltage (e.g. 4V). During the CHEI operation, the tunneling gate regions 10 of the selected and unselected cells can be left floating or can be alternately set at a potential disabling the hole carriers tunneling through the tri-layer structure. This can be done for example by applying a negative voltage at approximately −1.5V such that the bias across the insulator in the tri-layer structure is less than the hole barrier height. Ground potential is applied to the drain regions 22 for memory cell columns not containing the selected memory cell. Current at source regions 24 are kept below at a minimum level (e.g. about 10¹² amperes or lower) for memory cell columns not containing the selected memory cell. This can be done by, for example, leaving the source lines of those columns open. Ground potential is applied to the control gates 15 for memory cell rows not containing the selected memory cell. Thus, only the memory cell in the selected row and column is programmed.

The erase operation of this embodiment is the similar as that in the embodiment No. 1 for cell operation. For the example illustrated herein on the p+ polysilicon/nitride/pt polysilicon tri-layers structure, the voltage applied to various electrodes can be adjusted accordingly in order to properly inject ballistic hole using BCI mechanism. For example, the erase operation on a selected cell can be done by first applying a small voltage (e.g. −1.0 V) to its control gate region 15. A positive voltage is then applied to the tunneling gate 10 at a level where the relative difference to the control gate region 15 is in the vicinity of the voltage allowing hole-charges to surmount the valence band barrier height of the second layer 29. The bias at these nodes can be delivered through selecting word line, tunneling line, and SL/BLs of the selected cell at the same procedure as described hereinbefore. In accordance with the p+ polysilicon/nitride/p+ polysilicon tri-layer structure described herein, the valance band barrier height for hole charges is about 2.1 eV, and hence a typical voltage to the tunneling gate 10 can be on the order of approximately +1.1 to +1.5 volts. Then a negative voltage, on the order of 0 to −0.9 volts, can be applied to its floating gate region 20 through voltage capacitive coupled from the drain region 22, and the source region 24.

It is to be understood that the present invention is not limited to the illustrated herein and embodiments described above, but encompasses any and all variations falling within the scope of the appended claims. For example, although the present invention is illustrated in EEPROM, it should be apparent to those having ordinary skill in the art that it can be extended to any other type of nonvolatile memories (such as Electrical Programmable Memory or EPROM). Further, the foregoing method describes the use of appropriately doped polysilicon as the conductive material used to form the memory cell source/drain lines, tunneling gates and control gates, it should be apparent to those having ordinary skill in the art that any appropriate conductive material can be used. Therefore, as used in the claims, the terms “conductive materials” encompasses all such conductive materials such as polysilicon, polycide, aluminum, molybdenum, copper, titanium nitride, tantalum nitride etc. In addition, any appropriate insulator such as aluminum oxide, hafnium oxide, zirconitum nitride, tantalum pen-oxide, etc, can be used in place of oxide, oxynitride or nitride. Moreover, any appropriate material whose etch property differs from oxide (or any insulator) and from polysilicon (or any conductor) can be used in place of nitride. Further, as is apparent from the claims, not all method steps need be performed in the exact order illustrated or presented in the claims, but rather in any order that allows the proper formation of the memory cells of the present invention. The word lines, tunneling lines, drain lines, and source lines need not have a continuous width or shape, need not be straight, need not be in rectangular shape in their cross-section, but rather can be any size and shape that effectively connects to each memory cell in the appropriate memory cell row or column. The silicon blocks on a same row need not be all connected to form a block stripe, need not be in rectangular shape in their cross-section, but rather can be connected in a small group of blocks, and in trapezoidal shape in their cross-section that effectively implementing the fringing field effect in cell operations. The floating gates need not be in rectangular shape in their top view, need not be in rectangular in their folded portions, but rather can be any size and shape in their top view and in their folded portions that effectively store charges and effectively connects the drain and source regions in each memory cell. Furthermore, the top surface portion of the floating gate need not be co-planar with the isolation insulator surface, but rather can be at any level under or above the isolation insulator surface that effectively store charges, effectively capacitive-coupled with the control gate, and effectively connects the drain and source regions in each memory cell. Additionally, the bottom surface portion of the floating gate need not be parallel to the substrate surface, need not be flat, but rather can be with other shape that effectively store charges, effectively capacitive-coupled with the control gate, and effectively connects the drain and source regions in each memory cell. Moreover, source and drain regions, and/or source and drain lines, can be swapped. It should be understood that while the figures show the substrate uniformly doped, it is well known that any and/or all of the regions formed therein (source, drain, channel region, well region, etc.) can be formed in one or more well regions (of differently doped silicon). Furthermore, the first, the second, and the third insulators need not to be made of oxide, oxynitride, or nitride, but rather can be made of any appropriate insulator such as aluminum oxide, hafnium oxide, zirconium oxide, tantalum pen-oxide, etc, or can be made of the composite layers of these materials, e.g. oxide layer with and aluminum oxide layer or with zirconium oxide layer or other layers etc. Finally, the isolation regions need not have a continuous width or shape, need not be straight, need not be formed by oxide, need not be formed by junction-separation technique, but rather can be any isolation scheme that effectively divides active regions of memory cells in the appropriate memory row.

What is claimed is:

1. A nonvolatile memory device, comprising:
a substrate of a semiconductor material having a first conductivity type;
a semiconductor block over said substrate and having a first sidewall and a second sidewall opposite to each other and a top between said first sidewall and said second sidewall, said semiconductor block including a first region having a second conductivity type, a second region having said second conductivity type, and a third region between said first region and said second region and having said first conductivity type;
a folded floating gate over said third region of said semiconductor block, said folded floating gate having a first section adjacent said first sidewall of said semiconductor block, a second section adjacent said second sidewall of said semiconductor block, and a third section adjacent said top of said semiconductor block; and
a control gate disposed over said third section of said folded floating gate.

2. The nonvolatile memory device of claim 1, said semiconductor block having a height between approximately 0.1 micrometer (μm) and approximately 1 μm and a width between approximately 0.05 μm and approximately 0.8 μm.

3. The nonvolatile memory device of claim 1, said semiconductor block having a height and a width, said height being greater than said width.

4. The nonvolatile memory device of claim 1, said semiconductor block having a trapezoidal cross section.

5. The nonvolatile memory device of claim 1, further comprising an insulating layer between said semiconductor block and said substrate.

6. The nonvolatile memory device of claim !, said control gate including:
a polycrystalline silicon layer adjacent said third section of said folded floating gate; and
a metalized polycrystalline silicon layer over said polycrystalline silicon layer.

7. The nonvolatile memory device of claim 1, further comprising:
a dielectric layer over said control gate; and
a tunneling gate over said dielectric layer.

8. The nonvolatile memory device of claim 1, said semiconductor block further including a fourth region having said second conductivity type adjacent said second region, a fifth region of said second conductivity type, and a sixth region of said first conductivity type between said fourth region and said fifth region.

9. The nonvolatile memory device of claim 8, further comprising a second folded floating gate over said sixth region of said semiconductor block, said second folded floating gate having a first section adjacent said first sidewall of said semiconductor block, a second section adjacent said second sidewall of said semiconductor block, and a third section adjacent said top of said semiconductor block.

10. The nonvolatile-memory device of claim 9, said control gate being further disposed over said third section of said second folded floating gate.

11. The nonvolatile memory device of claim 10, further comprising:
a dielectric layer over said control gate;
a first tunneling gate over said dielectric layer and overlying said folded floating gate;
and a second tunneling gate over said dielectric layer and overlying said second folded floating gate.

12. The nonvolatile memory device of claim 10, further comprising:
a second semiconductor block over said substrate and having a first sidewall and a second sidewall opposite to each other and a top between said first sidewall and said second, sidewall, said second semiconductor block including:
a first region having said second conductivity type, a second region having said second conductivity type, and a third region between said first region and said second region and having said first conductivity type; and
a fourth region having said second conductivity type adjacent said second region, a fifth region of said second conductivity type, and a sixth region of said first conductivity type between said fourth region and said fifth region;
a third folded floating gate over said third region of said second semiconductor block, said third folded floating gate having a first section adjacent said first sidewall of said second semiconductor block, a second section adjacent said second sidewall of said second semiconductor block, and a third section adjacent said top of said second semiconductor block;
a fourth folded floating gate over said sixth region of said second semiconductor block, said third folded floating gate having a first section adjacent said first sidewall of said second semiconductor block, a second section adjacent said second sidewall of said second semiconductor block, and a third section adjacent said top of said second semiconductor block; and
a second control gate disposed over said third section of said third folded floating gate and said third section of said fourth folded floating gate.

13. The nonvolatile memory device of claim 12, further comprising:
a dielectric layer over said control gate and said second control gate;
a first tunneling gate over said dielectric layer overlying said folded floating gate and said third folded floating gate; and
a second tunneling gate over said dielectric layer overlying said second folded floating gate and said fourth folded floating gate.

14. The nonvolatile memory device of claim 12, further comprising an insulating layer insulating said semiconductor block and said second semiconductor block from said substrate.

15. The nonvolatile memory device of claim 1, further comprising:
a second semiconductor block over said substrate and having a first sidewall and a second sidewall opposite to each other and a top between said first sidewall and said second sidewall, said second semiconductor block including a first region having said second conductivity type, a second region having said second conductivity type, and a third region between said first region and said second region and having said first conductivity type;
a second folded floating gate over said third region of said second semiconductor block, said second folded floating gate having a first section adjacent said first sidewall of said second semiconductor block, a second section adjacent said second sidewall of said second semiconductor block, and a third section adjacent said top of said second semiconductor block.

16. The nonvolatile memory device of claim 15, further comprising an insulating layer insulating said semiconductor block and said second semiconductor block from said substrate.

17. The nonvolatile memory device of claim 15, said control gate being further disposed over said third section of said second folded floating gate.

18. The nonvolatile memory device of claim 17, further comprising:
a dielectric layer over said control gate;
a first tunneling gate over said dielectric layer overlying said folded floating gate; and
a second tunneling gate over said dielectric layer overlying said second folded floating gate.

19. The nonvolatile memory device of claim 15, further comprising a second control gate disposed over said third section of said second folded floating gate.

20. The nonvolatile memory device of claim 19, further comprising:
a dielectric layer over said control gate and said second control gate; and
a tunneling gate over said dielectric layer overlying said folded floating gate and said second folded floating gate.

21. A nonvolatile memory device, comprising:
a semiconductor substrate of a first conductivity type;
a plurality of semiconductor blocks over said substrate, each having a first sidewall and a second sidewall, and a top between said first sidewall and said second sidewall, each of said plurality of semiconductor blocks further including a first region of a second conductivity type, a second region of said second conductivity type, and a third region between said first region and said second region and of said first conductivity type;
a plurality of folded floating gates, each over said third region of a corresponding one of said plurality of semiconductor blocks and having a first section, a second section, and a third section adjacent said first sidewall, said second sidewall, and said top, respectively, of said corresponding semiconductor block; and
a plurality of control gates disposed over said plurality of folded floating gates.

22. The nonvolatile memory device of claim 21, wherein each of said semiconductor blocks has a height between approximately 0.1 micrometer (μm) and approximately 0.1 μm and a width between approximately 0.05 μm and approximately 0.8 μm.

23. The nonvolatile memory device of claim 21, wherein each of said semiconductor blocks has a trapezoidal cross section.

24. The nonvolatile memory device of claim 21, further comprising an insulating layer between said plurality of semiconductor blocks and said substrate.

25. The nonvolatile memory device of claim 21, further comprising a tunneling gate over said plurality of control gates.

26. The nonvolatile memory device of claim 21, wherein each of said plurality of semiconductor blocks further includes a fourth region having said second conductivity type adjacent said second region, a fifth region of said second conductivity type, and a sixth region of said first conductivity type between said fourth region and said fifth region.

27. The nonvolatile memory device of claim 26, further comprising a second plurality of folded floating gates, each over said sixth region of said corresponding semiconductor block and having a first section, a second section, and a third section adjacent said first sidewall, said second sidewall, and said top respectively, of said corresponding semiconductor block.

28. The nonvolatile memory device of claim 27, wherein said plurality of control gates are further disposed over said third section of said second plurality of folded floating gates.

29. The nonvolatile memory device of claim 28, further comprising:
a first tunneling gate over said plurality of folded floating gates; and
a second tunneling gate over said second plurality of folded, floating gates.

30. The nonvolatile memory device of claim 21, further comprising:
a second plurality of semiconductor blocks over said substrate, each including a first region of said second conductivity type, a second region of said second conductivity type, and a third region between said first region and said second region and of said first conductivity type;
a second plurality of folded floating gates, each over said third region of a corresponding one of said second plurality of semiconductor blocks; and
wherein said plurality of control gates are further disposed over said second plurality of folded floating gates.

31. A nonvolatile memory array, comprising:
a semiconductor substrate;
a plurality of semiconductor stripes over said substrate substantially parallel to one another, each having a first sidewall and a second sidewall, and a top between said first sidewall and said second sidewall, each of said plurality of stripes further including a plurality of sequentially arranged cells, each cell including a source region, a drain region, and a channel region there between;
a plurality of folded floating gates arranged in a plurality of rows and a plurality of columns, each over said channel region in a corresponding cell and having a first section, a second section, and a third section adjacent said first sidewall, said second sidewall, and said top, respectively, of a corresponding stripe; and
a plurality of control gates, each disposed over a row of said plurality of folded floating gates.

32. The nonvolatile memory array of claim 31, wherein each of said stripes has a height between approximately 0.1 micrometer (μm) and approximately 1 μm and a width between approximately 0.05 μm and approximately 0.8 μm.

33. The nonvolatile memory array of claim 31, wherein each of said stripes has a trapezoidal cross section.

34. The nonvolatile memory array of claim 31, further comprising an insulating layer between said plurality of stripes and said substrate.

35. The nonvolatile memory array of claim 31, further comprising a plurality tunneling gates over said plurality of control gates, each, overlying a column of said plurality of folded floating gates.
